(19) United States
(12) Patent Application Publication
(10) Pub. No.: US 2024/0224409 A1
(43) Pub. Date: Jul. 4, 2024

(54) ELECTRONIC DEVICE AND MANUFACTURING METHOD THEREOF

(71) Applicant: FUJIFILM Corporation, Tokyo (JP)

(72) Inventor: Yusuke FUJII, Kanagawa (JP)

(73) Assignee: FUJIFILM Corporation, Tokyo (JP)

(21) Appl. No.: 18/420,769

(22) Filed: Jan. 24, 2024

Related U.S. Application Data
(63) Continuation of application No. PCT/JP2022/024407, filed on Jun. 17, 2022.

(30) Foreign Application Priority Data
Aug. 10, 2021 (JP) 2021-130925

(51) Int. Cl. H05K 1/02; H05K 1/18

(52) U.S. Cl. CPC H05K 1/0216; H05K 1/0215; H05K 1/181; H05K 2201/0761; H05K 2203/013; H05K 2203/1377

(57) ABSTRACT

Provided are an electronic device including: a wiring board having a mounting surface; a ground electrode that defines a ground region on the mounting surface; an electronic component that is located on the mounting surface and is disposed in the ground region; a conductive component that is disposed adjacent to an outer edge of the ground electrode; an internal insulating protective layer that is disposed in the ground region and covers the electronic component; an external insulating protective layer that is disposed outside the ground region and covers the conductive component; and an electromagnetic wave shielding layer that is provided to extend over the internal insulating protective layer and the ground electrode and that covers the internal insulating protective layer and is electrically connected to the ground electrode, the electromagnetic wave shielding layer being a solidified product of an ink for forming an electromagnetic wave shielding layer, and a manufacturing method thereof.

### CROSS-REFERENCE TO RELATED APPLICATION

This application is a Continuation of International Application No. PCT/JP2022/024407, filed Jun. 17, 2022, which claims priority to Japanese Patent Application No. 2021-130925 filed Aug. 10, 2021. Each of the above applications is hereby expressly incorporated by reference, in its entirety, into the present application.

### BACKGROUND OF THE INVENTION

### 1. Field of the Invention

The present disclosure relates to an electronic device and a manufacturing method thereof.

### 2. Description of the Related Art

In the related art, studies have been conducted on an electronic apparatus (that is, an electronic device) having a structure in which an electronic component is mounted on a wiring board.

For example, JP2020-47939A discloses the following electronic apparatus as an electronic apparatus comprising: an electromagnetic shield, in which a manufacturing cost is suppressed, a reduction in thickness can be made, and a degree of freedom of a wiring circuit design is high.

The electronic apparatus disclosed in JP2020-47939A comprises: at least one electronic component; a conductive member that electromagnetically shields at least one electronic component; and a resin molded article in which at least a part of the at least one electronic component and at least a part of the conductive member that electromagnetically shields the electronic component are embedded and fixed, in which the at least one electronic component includes a first electronic component which is the electronic component subjected to the electromagnetic shielding, and a second electronic component that is not subjected to the electromagnetic shielding, at least a part of the second electronic component is embedded in the resin molded article, the first electronic component is fixed by an insulating member provided in a space formed by being surrounded by the conductive member, at least a part of the insulating member is embedded in the resin molded article together with at least a part of the first electronic component and at least a part of the conductive member, the conductive member is formed of a first conductive member embedded in the resin molded article, a second conductive member that is not embedded in the resin molded article, and at least one third conductive member provided between the first conductive member and the second conductive member, the first conductive member and the second conductive member are electrically connected to each other through the third conductive member, and the second electronic component is not in contact with the insulating member embedded in the resin molded article.

### SUMMARY OF THE INVENTION

The present inventor has studied manufacturing an electronic device by forming, on an electronic substrate comprising a wiring board having a mounting surface, a ground electrode that defines a ground region on the mounting surface, an electronic component that is located on the mounting surface and is disposed in the ground region, and a conductive component that is disposed adjacent to an outer edge of the ground electrode and is electrically insulated from the ground electrode, an internal insulating protective layer that is disposed in the ground region and covers the electronic component and an electromagnetic wave shielding layer that extends over the internal insulating protective layer and the ground electrode and that covers the internal insulating protective layer and is electrically connected to the ground electrode.

Further, from the viewpoint of simplification of a manufacturing process and a manufacturing apparatus, the present inventor has studied forming the electromagnetic wave shielding layer by a liquid process using an ink for forming an electromagnetic wave shielding layer instead of a vapor phase process (for example, sputtering, vapor deposition, or chemical vapor deposition).

However, as a result of these studies, it was found that, in a case in which the electromagnetic wave shielding layer is formed by the liquid process, a phenomenon in which the ink for forming an electromagnetic wave shielding layer flows out to an outside of the ground region and/or a phenomenon in which mist of the ink for forming an electromagnetic wave shielding layer is scattered to the outside occurs, and as a result, a short-circuit (specifically, a short-circuit that occurs between the formed electromagnetic wave shielding layer and the conductive component adjacent to the outer edge of the ground electrode, or the like) caused by the outflow and/or the mist of the ink for forming an electromagnetic wave shielding layer may occur.

According to one aspect of the present disclosure, there are provided an electronic device in which a short-circuit caused by an outflow and/or mist of an ink for forming an electromagnetic wave shielding layer is suppressed, and a manufacturing method thereof.

The specific methods for achieving the above-described object include the following aspects.

<1> An electronic device comprising: a wiring board having a mounting surface; a ground electrode that defines a ground region on the mounting surface; an electronic component that is located on the mounting surface and is disposed in the ground region; a conductive component that is disposed adjacent to an outer edge of the ground electrode and is electrically insulated from the ground electrode; an internal insulating protective layer that is disposed in the ground region and covers the electronic component; an external insulating protective layer that is disposed outside the ground region and covers the conductive component; and an electromagnetic wave shielding layer that is provided to extend over the internal insulating protective layer and the ground electrode and that covers the internal insulating protective layer and is electrically connected to the ground electrode, the electromagnetic wave shielding layer being a solidified product of an ink for forming an electromagnetic wave shielding layer.

<2> The electronic device according to <1>, in which a closest distance between the outer edge of the ground electrode and an edge of the conductive component is 0.1 mm to 10.0 mm.

<3> The electronic device according to <1> or <2>, in which a thickness T1 of the external insulating protective layer on the conductive component is 2 μm to 200 μm.

<4> The electronic device according to any one of <1> to <3>, in which a thickness T1 of the external insulating protective layer on the conductive component is thinner than a thickness T2 of the internal insulating protective layer on the electronic component.

<5> The electronic device according to any one of <1> to <4>, in which the internal insulating protective layer contains an acrylic resin and the external insulating protective layer contains an acrylic resin, or the internal insulating protective layer contains an epoxy resin and the external insulating protective layer contains an epoxy resin.

<6> A manufacturing method of an electronic device, the method comprising: a preparation step of preparing an electronic substrate including a wiring board having a mounting surface, a ground electrode that defines a ground region on the mounting surface, an electronic component that is located on the mounting surface and is disposed in the ground region, and a conductive component that is disposed adjacent to an outer edge of the ground electrode and is electrically insulated from the ground electrode; a first step of forming an internal insulating protective layer that covers the electronic component in the ground region; and a second step of forming an electromagnetic wave shielding layer that extends over the internal insulating protective layer and the ground electrode and that covers the internal insulating protective layer and is electrically connected to the ground electrode, as a solidified product of an ink for forming an electromagnetic wave shielding layer, in which an external insulating protective layer that covers the conductive component is formed outside the ground region before the second step.

<7> The manufacturing method of an electronic device according to <6>, in which, in the first step, the internal insulating protective layer and the external insulating protective layer are formed by using an ink for forming an insulating protective layer.

<8> The manufacturing method of an electronic device according to <7>, in which, in the first step, the ink for forming an insulating protective layer is applied by an ink jet recording method, a dispenser method, or a spray method to form the internal insulating protective layer and the external insulating protective layer.

<9> The manufacturing method of an electronic device according to <7> or <8>, in which the ink for forming an insulating protective layer is an active energy ray curable-type ink.

According to one aspect of the present disclosure, there are provided an electronic device in which a short-circuit caused by an outflow and/or mist of an ink for forming an electromagnetic wave shielding layer is suppressed, and a manufacturing method thereof.

### BRIEF DESCRIPTION OF THE DRAWINGS

FIG. 1A is a schematic plan view of an electronic substrate prepared in a preparation step in a manufacturing method according to an embodiment of the present disclosure.

FIG. 1B is a cross-sectional view taken along the line X-X of FIG. 1A.

FIG. 2A is a schematic plan view of an electronic substrate on which an internal insulating protective layer and an external insulating protective layer are formed in a first step in the manufacturing method according to the embodiment of the present disclosure.

FIG. 2B is a cross-sectional view taken along the line X-X of FIG. 2A.

FIG. 3A is a schematic plan view of an electronic substrate (that is, an electronic device according to the embodiment of the present disclosure) on which an electromagnetic wave shielding layer is formed in a second step in the manufacturing method according to the embodiment of the present disclosure.

FIG. 3B is a cross-sectional view taken along the line X-X of FIG. 3A.

### DESCRIPTION OF THE PREFERRED EMBODIMENTS

In the present disclosure, a numerical range shown using “to” indicates a range including the numerical values described before and after “to” as a lower limit and an upper limit.

In the present disclosure, in a case in which a plurality of substances corresponding to respective components in a composition are present, the amount of the respective components in the composition indicates the total amount of the plurality of substances present in the composition unless otherwise specified.

In a numerical range described in a stepwise manner in the present disclosure, an upper limit or a lower limit described in a certain numerical range may be replaced with an upper limit or a lower limit in another numerical range described in a stepwise manner or a value described in an example.

In the present disclosure, the term “step” denotes not only an individual step but also a step which is not clearly distinguishable from another step as long as an effect expected from the step can be achieved.

In the present disclosure, a combination of preferred aspects is a more preferred embodiment.

### [Electronic Device]

An electronic device of the present disclosure comprises: a wiring board having a mounting surface; a ground electrode that defines a ground region on the mounting surface; an electronic component that is located on the mounting surface and is disposed in the ground region; a conductive component (hereinafter, also referred to as an “adjacent conductive component”) that is disposed adjacent to an outer edge of the ground electrode and is electrically insulated from the ground electrode; an internal insulating protective layer that is disposed in the ground region and covers the electronic component; an external insulating protective layer that is disposed outside the ground region and covers the conductive component; and an electromagnetic wave shielding layer that is provided to extend over the internal insulating protective layer and the ground electrode and that covers the internal insulating protective layer and is electrically connected to the ground electrode, the electromagnetic wave shielding layer being a solidified product of an ink for forming an electromagnetic wave shielding layer.

According to the electronic device of the present disclosure, a short-circuit caused by an outflow and/or the mist of the ink for forming an electromagnetic wave shielding layer is suppressed.

Hereinafter, such an effect will be described in more detail.

As described above, the present inventor has studied manufacturing an electronic device by forming, on an electronic substrate comprising the wiring board, the ground (GND) electrode, the electronic component disposed in the ground region, and the adjacent conductive component, the internal insulating protective layer that is disposed in the ground region and covers the electronic component and the electromagnetic wave shielding layer that extends over the internal insulating protective layer and the ground electrode and that covers the internal insulating protective layer and is electrically connected to the ground electrode.

Further, from the viewpoint of simplification of a manufacturing process and a manufacturing apparatus, the present inventor has studied forming the electromagnetic wave shielding layer by a liquid process using an ink for forming an electromagnetic wave shielding layer instead of a vapor phase process (for example, sputtering, vapor deposition, or chemical vapor deposition).

However, as a result of these studies, it was found that, in a case in which the electromagnetic wave shielding layer is formed by the liquid process, a phenomenon in which the ink for forming an electromagnetic wave shielding layer flows out to an outside of the ground region and/or a phenomenon in which the ink for forming an electromagnetic wave shielding layer is scattered to the outside of the ground region occurs, and as a result, a short-circuit (specifically, a short-circuit that occurs between the formed electromagnetic wave shielding layer and the adjacent conductive component) caused by the outflow and/or the mist of the ink for forming an electromagnetic wave shielding layer may occur.

With respect to the above-described problem, in the electronic device of the present disclosure, the adjacent conductive component (that is, the conductive component adjacent to the outer edge of the ground electrode) is covered with an external insulating protective film.

Thereby, even in a case in which the ink for forming an electromagnetic wave shielding layer flows out of the ground region and/or even in a case in which the mist of the ink for forming an electromagnetic wave shielding layer is scattered to the outside of the ground region, insulating properties between the formed electromagnetic wave shielding layer and the adjacent conductive component are secured.

As a result, a short-circuit caused by the outflow and/or the mist of the ink for forming an electromagnetic wave shielding layer is suppressed.

In the present disclosure, the term “conductive” means properties of having a volume resistivity of less than 10⁸ Ωcm.

In the present disclosure, the insulating properties mean properties of having a volume resistivity of 10¹⁰ Ωcm or more.

In the present disclosure, the outer edge of the ground electrode means an edge on a side far from the ground region among edges of the ground electrode in a case in which the electronic substrate is seen in plan view.

### <Embodiment of Manufacturing Method of Electronic Device>

Hereinafter, an embodiment of a manufacturing method of an electronic device of the present disclosure will be shown.

The manufacturing method of an electronic device according to the embodiment of the present disclosure includes: a preparation step of preparing an electronic substrate including a wiring board having a mounting surface, a ground electrode that defines a ground region on the mounting surface, an electronic component that is located on the mounting surface and is disposed in the ground region, and an adjacent conductive component (that is, a conductive component that is disposed adjacent to an outer edge of the ground electrode and is electrically insulated from the ground electrode); a first step of forming an internal insulating protective layer that covers the electronic component in the ground region; and a second step of forming an electromagnetic wave shielding layer that extends over the internal insulating protective layer and the ground electrode and that covers the internal insulating protective layer and is electrically connected to the ground electrode, as a solidified product of an ink for forming an electromagnetic wave shielding layer, in which an external insulating protective layer that covers the adjacent conductive component is formed outside the ground region before the second step.

The manufacturing method of an electronic device according to the embodiment of the present disclosure may include other steps as necessary.

In the manufacturing method of an electronic device according to the embodiment of the present disclosure, before the second step of forming the electromagnetic wave shielding layer by using the ink for forming an electromagnetic wave shielding layer, the external insulating protective layer that covers the adjacent conductive component is formed outside the ground region.

Therefore, even in a case in which the above-described ink for forming an electromagnetic wave shielding layer flows out of the ground region and/or even in a case in which the mist of the ink for forming an electromagnetic wave shielding layer is scattered to the outside of the ground region, insulating properties between the formed electromagnetic wave shielding layer and the adjacent conductive component (that is, the conductive component adjacent to the outer edge of the ground electrode) are secured.

As a result, a short-circuit caused by the outflow and/or the mist of the ink for forming an electromagnetic wave shielding layer is suppressed.

Hereinafter, an example of the manufacturing method of an electronic device according to an embodiment of the present disclosure will be described with reference to the drawings. Note that the manufacturing method of an electronic device according to the embodiment of the present disclosure is not limited to the following example.

In the following description, substantially the same elements (for example, components or parts) may be designated by the same reference numerals, and redundant description thereof may be omitted.

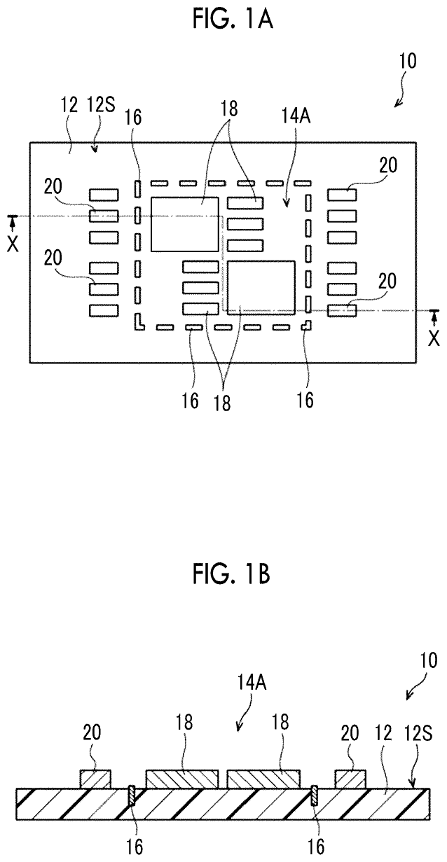

FIG. 1A is a schematic plan view of the electronic substrate prepared in the preparation step, and FIG. 1B is a cross-sectional view taken along the line X-X of FIG. 1A.

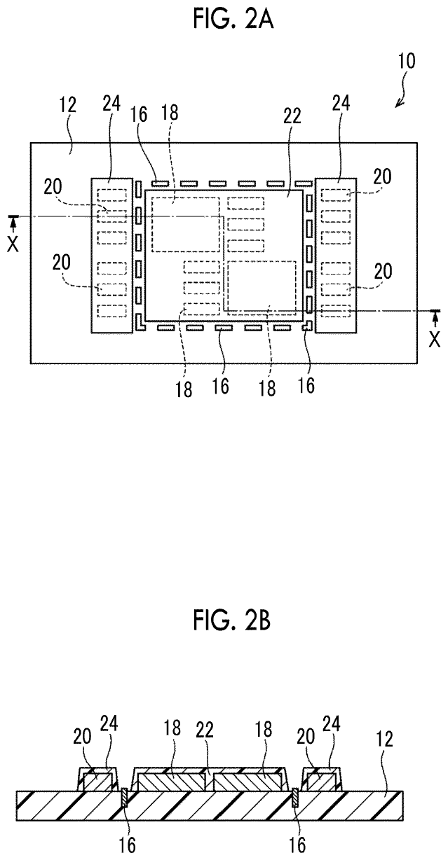

FIG. 2A is a schematic plan view of the electronic substrate on which the insulating protective layer is formed in the first step, and FIG. 2B is a cross-sectional view taken along the line X-X of FIG. 2A.

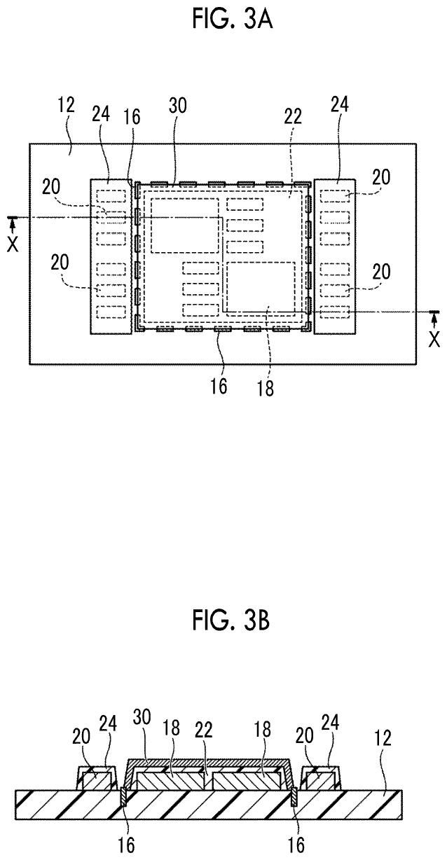

FIG. 3A is a schematic plan view of the electronic substrate (that is, the electronic device of the present embodiment) on which the electromagnetic wave shielding layer is formed in the second step, and FIG. 3B is a cross-sectional view taken along the line X-X of FIG. 3A.

### —Preparation Step—

As shown in FIGS. 1A and 1B, in the preparation step in the present example, an electronic substrate 10 comprising a wiring board 12 having a mounting surface 12S, a ground electrode 16 that defines a ground region 14A on the mounting surface 12S, an electronic component 18 that is located on the mounting surface 12S and is disposed in the ground region 14A, and an adjacent conductive component 20 that is disposed adjacent to an outer edge of the ground electrode 16 and is electrically insulated from the ground electrode 16 is prepared.

The preparation step may be a step of simply preparing the electronic substrate 10 manufactured in advance, or may be a step of manufacturing the electronic substrate 10.

As a manufacturing method of the electronic substrate 10, for example, a known manufacturing method of an electronic substrate in which an electronic component is mounted on a printed wiring board can be appropriately referred to.

As the wiring board 12, a substrate on which a wiring is formed, for example, a printed wiring board can be used.

The wiring board 12 may include an electrode other than the ground electrode 16, a solder resist layer, and the like.

The ground electrode 16 is an electrode to which a ground (GND) potential is applied.

In this example, a plurality of the electronic components 18 are mounted in the ground region 14A defined by the ground electrode 16.

In this example, the adjacent conductive component 20 that is disposed adjacent to the outer edge of the ground electrode 16 and is electrically insulated from the ground electrode 16 is mounted outside the ground region 14A.

Examples of the adjacent conductive component 20 include an electronic component, an electrode, and a wiring.

As shown in FIG. 1A, the ground electrode 16 in this example is formed in a discontinuous pattern (specifically, a divided line pattern), but the ground electrode in the present disclosure is not limited to this example. For example, the ground electrode in the present disclosure may be formed as a continuous pattern (that is, a line pattern that is not divided).

In addition, the ground electrode 16 in this example is formed as an annular pattern that completely goes around the plurality of electronic components 18.

However, the ground electrode 16 in the present disclosure is not limited to the annular pattern, and need only have a pattern (for example, a U-shaped pattern) capable of defining the ground region 14A.

From the viewpoint of further reducing an influence of the electromagnetic waves from the outside on the plurality of electronic components 18, the ground electrode 16 preferably surrounds a region where the plurality of electronic components are disposed by half or more, and more preferably surrounds the region by ¾ or more.

In addition, as shown in FIG. 1B, the ground electrode 16 in this example is formed such that a part of the ground electrode 16 in a thickness direction is embedded in the wiring board 12, but the ground electrode in the present disclosure is not limited to this example. For example, the ground electrode in the present disclosure may be formed such that the entirety of the ground electrode in the thickness direction is embedded. In addition, the ground electrode in the present disclosure may be formed on a surface of the wiring board 12 instead of being embedded in the wiring board 12. In addition, the ground electrode in the present disclosure may be formed as a pattern that penetrates the wiring board 12.

The plurality of electronic components 18 mounted in the ground region 14A may be electronic components having the same design or may be electronic components having different designs. In addition, the number of the electronic components mounted in the ground region is not limited to plural, and may be only one.

Similarly, a plurality of the adjacent conductive components 20 mounted outside the ground region 14A may be electronic components having the same design or may be electronic components having different designs. In addition, the number of the electronic components mounted outside the ground region is not limited to plural, and may be only one.

Examples of the electronic component 18 include a semiconductor chip such as an integrated circuit (IC), a capacitor, and a transistor.

Examples of the adjacent conductive component 20 include a semiconductor chip such as an integrated circuit; an electronic component such as a capacitor and a transistor; a wiring; and an electrode.

### —First Step—

As shown in FIGS. 2A and 2B, in the first step, an internal insulating protective layer 22 that covers the plurality of electronic components 18 mounted in the ground region 14A is formed.

The internal insulating protective layer 22 is formed in a region that extends over the plurality of electronic components 18 and a periphery of the plurality of electronic components 18 in the ground region 14A.

The function of the internal insulating protective layer is, for example, a function of protecting the electronic components and a function of suppressing a short-circuit between the electronic components and other conductive components (for example, an electromagnetic wave shielding layer).

In the first step of this example, the internal insulating protective layer 22 and an external insulating protective layer 24 are both formed in the same process by using the same ink for forming an insulating protective layer (for example, an ink).

The external insulating protective layer 24 is an insulating protective layer that is disposed outside the ground region 14A and covers the adjacent conductive components 20.

The function of the external insulating protective layer is, for example, a function of protecting the adjacent conductive components and a function of suppressing a short-circuit between the adjacent conductive components and other conductive components (for example, an electromagnetic wave shielding layer).

Although a pattern of the external insulating protective layer 24 of this example is a pattern that extends over the plurality of adjacent conductive components 20, the pattern of the external insulating protective layer is not limited to this example.

The pattern of the external insulating protective layer in the present disclosure may be a plurality of patterns that cover each of the plurality of adjacent conductive components 20 one by one.

In this example, the internal insulating protective layer 22 and the external insulating protective layer 24 are formed in the same step (that is, the first step), but a timing of forming the external insulating protective layer in the manufacturing method according to the present embodiment is not limited to this example.

The formation of the external insulating protective layer in the manufacturing method according to the present embodiment need only be performed before the second step (that is, the step of forming the electromagnetic wave shielding layer). For example, the formation of the external insulating protective layer may be performed after the first step and before the second step (that is, after the formation of the internal insulating protective layer), or may be performed after the preparation step and before the first step (that is, before the formation of the internal insulating protective layer).

A material (for example, a composition or a sheet material) for forming the internal insulating protective layer and a material (for example, a composition or a sheet material) for forming the external insulating protective layer may be the same as or different from each other.

For the sheet material, for example, an insulating sheet material disclosed in JP2019-91866A can be referred to.

In the first step, as in the above example, it is preferable that the internal insulating protective layer and the external insulating protective layer are formed by using the ink for forming an insulating protective layer.

As described above, the aspect in which the internal insulating protective layer and the external insulating protective layer are formed in the same step by using the same composition is advantageous in terms of reducing the number of steps (that is, productivity of the electronic device) compared to an aspect in which the internal insulating protective layer and the external insulating protective layer are formed in separate steps.

The ink for forming an insulating protective layer is preferably an active energy ray curable-type ink.

In particular, in a case in which the internal insulating protective layer and the external insulating protective layer are formed by using the ink for forming an insulating protective layer in the first step, the ink for forming an insulating protective layer is preferably an active energy ray curable-type ink.

In a case in which the ink for forming an insulating protective layer is an active energy ray curable-type ink, it is advantageous from the viewpoint of productivity and durability of the internal insulating protective layer and/or the external insulating protective layer.

An application method for applying the ink for forming an insulating protective layer onto the electronic substrate is not particularly limited.

The first step in a case in which the internal insulating protective layer and the external insulating protective layer are formed by using the ink for forming an insulating protective layer is preferably a step of applying the ink for forming an insulating protective layer by an ink jet recording method, a dispenser method, or a spray method to form the internal insulating protective layer and the external insulating protective layer.

As the application method of the ink for forming an insulating protective layer, an ink jet recording method is particularly preferable.

A preferred aspect of the ink jet recording method as the application method of the ink for forming an insulating protective layer is the same as a preferred aspect of an ink jet recording method as an application method of the ink for forming an electromagnetic wave shielding layer, which will be described below.

### —Second Step—

As shown in FIGS. 3A and 3B, in the second step, an electromagnetic wave shielding layer 30 that extends over the internal insulating protective layer 22 and at least a part of the ground electrode 16 and that covers the internal insulating protective layer 22 and is electrically connected to the ground electrode 16, the electromagnetic wave shielding layer 30 being a solidified product of the ink for forming an electromagnetic wave shielding layer, is formed by using the ink for forming an electromagnetic wave shielding layer.

The electromagnetic wave shielding layer 30 is formed by applying the ink for forming an electromagnetic wave shielding layer into the ground region 14A and solidifying the ink for forming an electromagnetic wave shielding layer.

Preferred ranges of the ink for forming an electromagnetic wave shielding layer and a method for forming an electromagnetic wave shielding layer will be described below.

The electromagnetic wave shielding layer is a layer for reducing the influence of electromagnetic waves on the electronic components by shielding the electromagnetic waves applied to the electronic components.

In the present disclosure, the performance of such an electromagnetic wave shielding layer is also referred to as “electromagnetic wave-shielding properties”.

The electromagnetic wave-shielding properties of the electromagnetic wave shielding layer are exhibited by disposing the electromagnetic wave shielding layer on the electronic components with the internal insulating protective layer being interposed therebetween.

In addition, the electromagnetic wave-shielding properties of the electromagnetic wave shielding layer are exhibited in a case in which a ground (GND) potential is applied to the electromagnetic wave shielding layer. Therefore, the electromagnetic wave shielding layer has conductivity as a premise of the electromagnetic wave shielding layer.

In the manufacturing method according to the present example, in a case in which the ink for forming an electromagnetic wave shielding layer is applied into the ground region 14A and solidified to form the electromagnetic wave shielding layer 30, the external insulating protective layer 24 already exists on the adjacent conductive component 20 outside the ground region 14A.

Therefore, even in a case in which the ink for forming an electromagnetic wave shielding layer flows out of the ground region 14A, the insulating properties between the formed electromagnetic wave shielding layer 30 and the adjacent conductive component 20 are secured.

Therefore, a short-circuit caused by the outflow and/or the mist of the ink for forming an electromagnetic wave shielding layer is suppressed.

Hereinafter, preferred ranges of the electronic device and the manufacturing method of the electronic device of the present disclosure will be described.

<Distance between Ground Electrode and Adjacent Conductive Component>

The closest distance between the outer edge of the ground electrode (for example, the ground electrode 16) and the edge of the adjacent conductive component is preferably 0.05 mm to 20.0 mm, and more preferably 0.1 mm to 10.0 mm.

In a case in which the closest distance is 0.05 mm or more, it is easy to form the external insulating protective layer such that an edge of the external insulating protective layer is disposed between the outer edge of the ground electrode and the edge of the adjacent conductive component. Therefore, since it is easier to secure the insulating properties between the ground electrode and the adjacent conductive component, the short-circuit caused by the outflow and/or the mist of the ink for forming an electromagnetic wave shielding layer is more suppressed.

In a case in which the closest distance is 20.0 mm or less, space-saving properties are excellent.

In addition, a case in which the closest distance is 20.0 mm or less and the external insulating protective layer is not provided serves as a condition for causing the short-circuit to likely to occur due to the outflow and/or the mist of the ink for forming an electromagnetic wave shielding layer. Accordingly, in a case in which the closest distance is 20.0 mm or less, the significance of providing the external insulating protective layer is greater.

### <Thickness T1 of External Insulating Protective Layer on Conductive Component>

A thickness T1 of the external insulating protective layer on the conductive component is preferably 1 μm to 200 μm, more preferably 2 μm to 200 μm, and still more preferably 3 μm to 150 μm.

In a case in which the thickness T1 is 1 μm or more, the effect (that is, the suppression of the short-circuit caused by the outflow and/or the mist of the ink for forming an electromagnetic wave shielding layer) of the external insulating protective layer is more effectively exhibited.

In a case in which the thickness T1 is 200 μm or less, it is advantageous in that it is easy to reduce the weight of the electronic device.

The thickness T1 of the external insulating protective layer on the conductive component is preferably thinner than a thickness T2 of the internal insulating protective layer on the electronic component.

Thereby, formation stability of the electromagnetic wave shielding layer is further improved.

Specifically, in a case of forming the electromagnetic wave shielding layer in the present disclosure, an application member (for example, a jetting nozzle) for applying the ink for forming an electromagnetic wave shielding layer is moved from the outside of the ground region onto the internal insulating protective layer in the ground region, and applies the ink for forming an electromagnetic wave shielding layer at this position. In the above-described preferred aspect, since the height of the external insulating protective layer is likely to be relatively low as compared with the height of the internal insulating protective layer on the electronic component, the external insulating protective layer is less likely to interfere the movement of the application member (for example, a jetting nozzle) onto the internal insulating protective layer. Therefore, the formation stability in a case of forming the electromagnetic wave shielding layer on the internal insulating protective layer is further improved.

In a case in which a value obtained by subtracting the thickness T1 from the thickness T2 is defined as a thickness difference [T2−T1], the thickness difference [T2−T1] is preferably 5 μm to 200 μm, and more preferably 10 μm to 100 μm.

In the present disclosure, unless otherwise specified, the height means a height based on the mounting surface of the wiring board.

Both the height and thickness of each component (or each layer) are measured based on an optical micrograph obtained by imaging a cross section of the electronic device.

The height of the electronic component disposed in the ground region is preferably 100 μm or more, more preferably 200 μm or more, and still more preferably 300 μm or more.

The height of the electronic component is preferably 1000 μm or less, and more preferably 800 μm or less.

A height of the adjacent conductive component (that is, the conductive component that is disposed adjacent to the outer edge of the ground electrode and is electrically insulated from the ground electrode) is preferably 50 μm or more, more preferably 100 μm or more, and still more preferably 200 μm or more.

The height of the adjacent conductive component is preferably 1000 μm or less, and more preferably 800 μm or less.

The height of the ground electrode is preferably −10 μm or more, more preferably 0 μm or more, and still more preferably 5 μm or more.

The height of the ground electrode is preferably 100 μm or less, more preferably 50 μm or less, and still more preferably 30 μm or less.

### <Materials of Internal Insulating Protective Layer and External Insulating Protective Layer>

In the electronic device of the present disclosure, it is preferable that the internal insulating protective layer contains an acrylic resin and the external insulating protective layer contains an acrylic resin, and the internal insulating protective layer contains an epoxy resin and the external insulating protective layer contains an epoxy resin, or the internal insulating protective layer contains a silicone resin and the external insulating protective layer contains a silicone resin.

In such a preferred aspect, since the internal insulating protective layer and the external insulating protective layer are easily formed by using the same composition for forming an insulating protective layer, it is advantageous in that the number of steps can be reduced (that is, the productivity of the electronic device).

In the electronic device of the present disclosure, it is more preferable that the internal insulating protective layer contains an acrylic resin and the external insulating protective layer contains an acrylic resin, or the internal insulating protective layer contains an epoxy resin and the external insulating protective layer contains an epoxy resin.

For example, each of the internal insulating protective layer containing an acrylic resin and the external insulating protective layer containing an acrylic resin is preferably formed using a composition for forming an insulating protective layer containing a (meth)acrylate monomer.

Each of the internal insulating protective layer containing an epoxy resin and the external insulating protective layer containing an epoxy resin is preferably formed using a composition for forming an insulating protective layer containing an epoxy monomer.

Each of the internal insulating protective layer containing a silicone resin and the external insulating protective layer containing a silicone resin is preferably formed using a composition for forming an insulating protective layer containing a silicone-based monomer.

A preferred aspect of the composition for forming an insulating protective layer will be described below.

Next, preferred aspects of the ink for forming an electromagnetic wave shielding layer, the method for forming an electromagnetic wave shielding layer, the ink for forming an insulating protective layer, and a method for forming an insulating protective layer will be described.

### <Ink for Forming Electromagnetic Wave Shielding Layer>

The electromagnetic wave shielding layer in the present disclosure is a solidified product of the ink for forming an electromagnetic wave shielding layer.

That is, the electromagnetic wave shielding layer in the present disclosure is formed by applying the ink for forming an electromagnetic wave shielding layer and solidifying the ink for forming an electromagnetic wave shielding layer.

As the ink for forming an electromagnetic wave shielding layer, an ink containing metal particles (hereinafter, also referred to as a “metal particle ink”), an ink containing a metal complex (hereinafter, also referred to as a “metal complex ink”), or an ink containing a metal salt (hereinafter, also referred to as a “metal salt ink”) is preferable, and a metal salt ink or a metal complex ink is more preferable.

### (Metal Particle Ink)

The metal particle ink is, for example, an ink composition obtained by dispersing metal particles in a dispersion medium.

### —Metal Particles—

Examples of the metal constituting the metal particles include base metal and noble metal particles. Examples of the base metal include nickel, titanium, cobalt, copper, chromium, manganese, iron, zirconium, tin, tungsten, molybdenum, and vanadium. Examples of the noble metal include gold, silver, platinum, palladium, iridium, osmium, ruthenium, rhodium, rhenium, and alloys containing these metals. Among these, from the viewpoint of the electromagnetic wave-shielding properties, the metal constituting the metal particles preferably includes at least one selected from the group consisting of silver, gold, platinum, nickel, palladium, and copper, and more preferably includes silver.

An average particle diameter of the metal particles is not particularly limited, but is preferably 10 nm to 500 nm, and more preferably 10 nm to 200 nm. In a case in which the average particle diameter is in the above range, a baking temperature of the metal particles is lowered, which improves process suitability for forming the electromagnetic wave shielding layer. Particularly, in a case in which the metal particle ink is applied by using a spray method or an ink jet recording method, jettability is improved, which tends to improve pattern forming properties and film thickness uniformity of the electromagnetic wave shielding layer. The average particle diameter mentioned herein means an average value of primary particle diameters of the metal particles (average primary particle diameter).

The average particle diameter of the metal particles is measured by a laser diffraction/scattering method. The average particle diameter of the metal particles is, for example, a value obtained by measuring a 50% cumulative volume-based diameter (D50) three times and calculating an average value of D50 measured three times, and can be measured by using a laser diffraction/scattering-type particle size distribution analyzer (trade name “LA-960” manufactured by Horiba, Ltd.).

In addition, the metal particle ink may contain metal particles having an average particle diameter of 500 nm or more, as necessary. In a case in which the metal particle ink contains metal particles having an average particle diameter of 500 nm or more, a melting point of the nm-sized metal particles is lowered around the μm-sized metal particles, which makes it possible to bond the electromagnetic wave shielding layer.

The content of the metal particles in the metal particle ink is preferably 10% by mass to 90% by mass, and more preferably 20% by mass to 50% by mass, with respect to the total amount of the metal particle ink. In a case in which the content of the metal particles is 10% by mass or more, a surface resistivity is further reduced. In a case in which the content of the metal particles is 90% by mass or less, jettability is improved in a case in which the metal particle ink is applied by using an ink jet recording method.

In addition to the metal particles, the metal particle ink may contain, for example, a dispersing agent, a resin, a dispersion medium, a thickener, and a surface tension adjuster.

—Dispersing Agent—

The metal particle ink may contain a dispersing agent that adheres to at least a part of a surface of the metal particles. The dispersing agent substantially constitutes metal colloidal particles, together with the metal particles. The dispersing agent has an action of coating the metal particles to improve dispersibility of the metal particles and prevent aggregation. The dispersing agent is preferably an organic compound capable of forming the metal colloidal particles. From the viewpoint of the electromagnetic wave-shielding properties and dispersion stability, the dispersing agent is preferably an amine, a carboxylic acid, an alcohol, or a resin dispersing agent.

The metal particle ink may contain one dispersing agent or two or more dispersing agents.

Examples of the amine include saturated or unsaturated aliphatic amines. Among these, the amine is preferably an aliphatic amine having 4 to 8 carbon atoms. The aliphatic amine having 4 to 8 carbon atoms may be linear or branched, or may have a ring structure.

Examples of the aliphatic amine include butylamine, normal pentylamine, isopentylamine, hexylamine, 2-ethylhexylamine, and octylamine.

Examples of the amine having an alicyclic structure include cycloalkylamines such as cyclopentylamine and cyclohexylamine.

Examples of an aromatic amine include aniline.

The amine may have a functional group other than an amino group. Examples of the functional group other than an amino group include a hydroxy group, a carboxy group, an alkoxy group, a carbonyl group, an ester group, and a mercapto group.

Examples of the carboxylic acid include formic acid, oxalic acid, acetic acid, hexanoic acid, acrylic acid, octylic acid, oleic acid, tianshic acid, ricinoleic acid, gallic acid, and salicylic acid. A carboxy group, which is a part of the carboxylic acid, may form a salt with a metal ion. The salt may be formed of one metal ion or two or more metal ions.

The carboxylic acid may have a functional group other than the carboxy group. Examples of the functional group other than the carboxy group include an amino group, a hydroxy group, an alkoxy group, a carbonyl group, an ester group, and a mercapto group.

Examples of the alcohol include a terpene-based alcohol, an allyl alcohol, and an oleyl alcohol. The alcohol is likely to be coordinated with the surface of the metal particles, and can suppress the aggregation of the metal particles.

Examples of the resin dispersing agent include a dispersing agent that has a nonionic group as a hydrophilic group and can be uniformly dissolved in a solvent. Examples of the resin dispersing agent include polyvinylpyrrolidone, polyethylene glycol, a polyethylene glycol-polypropylene glycol copolymer, polyvinyl alcohol, polyallylamine, and a polyvinyl alcohol-polyvinyl acetate copolymer. A molecular weight of the resin dispersing agent is preferably 1000 to 50000, and more preferably 1000 to 30000, in terms of a weight-average molecular weight.

The content of the dispersing agent in the metal particle ink is preferably 0.5% by mass to 50% by mass, and more preferably 1% by mass to 30% by mass, with respect to the total amount of the metal particle ink.

### —Dispersion Medium—

The metal particle ink preferably contains a dispersion medium. A type of the dispersion medium is not particularly limited, and examples thereof include a hydrocarbon, an alcohol, and water.

The metal particle ink may contain one dispersion medium or two or more dispersion media. The dispersion medium contained in the metal particle ink is preferably volatile. A boiling point of the dispersion medium is preferably 50° C. to 250° C., more preferably 70° C. to 220° C., and still more preferably 80° C. to 200° C. In a case in which the boiling point of the dispersion medium is 50° C. to 250° C., the stability and baking properties of the metal particle ink tend to be simultaneously achieved.

Examples of the hydrocarbon include an aliphatic hydrocarbon and an aromatic hydrocarbon.

Examples of the aliphatic hydrocarbon include a saturated or unsaturated aliphatic hydrocarbon such as tetradecane, octadecane, heptamethylnonane, tetramethylpentadecane, hexane, heptane, octane, nonane, decane, tridecane, methylpentane, normal paraffin, or isoparaffin.

Examples of the aromatic hydrocarbon include toluene and xylene.

Examples of the alcohol include an aliphatic alcohol and an alicyclic alcohol. In a case in which an alcohol is used as the dispersion medium, the dispersing agent is preferably an amine or a carboxylic acid.

Examples of the aliphatic alcohol include a saturated or unsaturated aliphatic alcohol having 6 to 20 carbon atoms that may contain an ether bond in a chain, such as heptanol, octanol (for example, 1-octanol, 2-octanol, or 3-octanol), decanol (for example, 1-decanol), lauryl alcohol, tetradecyl alcohol, cetyl alcohol, 2-ethyl-1-hexanol, octadecyl alcohol, hexadecenol, and oleyl alcohol.

Examples of the alicyclic alcohol include a cycloalkanol such as cyclohexanol; a terpene alcohol such as terpineol (including α, β, and γ isomers, or any mixture of these) or dihydroterpineol; myrtenol, sobrerol, menthol, carveol, perillyl alcohol, pinocarveol, and verbenol.

The dispersion medium may be water. From the viewpoint of adjusting physical properties such as viscosity, surface tension, and volatility, the dispersion medium may be a mixed solvent of water and another solvent. Another solvent to be mixed with water is preferably an alcohol. The alcohol used together with water is preferably an alcohol that is miscible with water and has a boiling point of 130° C. or lower. Examples of the alcohol include 1-propanol, 2-propanol, 1-butanol, 2-butanol, tert-butanol, 1-pentanol, ethylene glycol monomethyl ether, ethylene glycol monoethyl ether, ethylene glycol monopropyl ether, propylene glycol monomethyl ether.

The content of the dispersion medium in the metal particle ink is preferably 1% by mass to 50% by mass, with respect to the total amount of the metal particle ink. In a case in which the content of the dispersion medium is 1% by mass to 50% by mass, the metal particle ink can obtain sufficient conductivity as the ink for forming an electromagnetic wave shielding layer. The content of the dispersion medium is more preferably 10% by mass to 45% by mass, and still more preferably 20% by mass to 40% by mass.

### —Resin—

The metal particle ink may contain a resin. Examples of the resin include polyester, polyurethane, a melamine resin, an acrylic resin, a styrene-based resin, a polyether, and a terpene resin.

The metal particle ink may contain one resin or two or more resins.

The content of the resin in the metal particle ink is preferably 0.1% by mass to 5% by mass with respect to the total amount of the metal particle ink.

### —Thickener—

The metal particle ink may contain a thickener. Examples of the thickener include clay minerals such as clay, bentonite, and hectorite; cellulose derivatives such as methyl cellulose, carboxymethyl cellulose, hydroxyethyl cellulose, hydroxypropyl cellulose, and hydroxypropyl methyl cellulose; and polysaccharides such as xanthan gum and guar gum.

The metal particle ink may contain one thickener or two or more thickeners.

The content of the thickener in the metal particle ink is preferably 0.1% by mass to 5% by mass with respect to the total amount of the metal particle ink.

### —Surfactant—

The metal particle ink may contain a surfactant. In a case in which the metal particle ink contains a surfactant, a uniform electromagnetic wave shielding layer is likely to be formed.

The surfactant may be any of an anionic surfactant, a cationic surfactant, or a nonionic surfactant. Among these, the surfactant is preferably a fluorine-based surfactant from the viewpoint of being able to adjust the surface tension with a small amount of content. In addition, the surfactant is preferably a compound having a boiling point higher than 250° C.

The viscosity of the metal particle ink is not particularly limited. The viscosity of the metal particle ink need only be 0.01 Pa·s to 5000 Pa·s, and is preferably 0.1 Pa·s to 100 Pa·s. In a case in which the metal particle ink is applied by using a spray method or an ink jet recording method, the viscosity of the metal particle ink is preferably 1 mPa·s to 100 mPa·s, more preferably 2 mPa·s to 50 mPa·s, and still more preferably 3 mPa·s to 30 mPa·s.

The viscosity of the metal particle ink is a value measured at 25° C. by using a viscometer. The viscosity is measured using, for example, a VISCOMETER TV-22 type viscometer (manufactured by Toki Sangyo Co., Ltd.).

The surface tension of the metal particle ink is not particularly limited, and is preferably 20 mN/m to 45 mN/m and more preferably 25 mN/m to 40 mN/m.

The surface tension is a value measured at 25° C. by using a surface tension meter.

The surface tension of the metal particle ink is measured using, for example, DY-700 (manufactured by Kyowa Interface Science Co., Ltd.).

### —Manufacturing Method of Metal Particles—

The metal particles may be a commercially available product or may be manufactured by a known method. Examples of a manufacturing method of the metal particles include a wet reduction method, a vapor phase method, and a plasma method. Preferred examples of the manufacturing method of the metal particles include a wet reduction method capable of manufacturing metal particles having an average particle diameter of 200 nm or less and having a narrow particle size distribution. Examples of the manufacturing method of the metal particles by a wet reduction method include the method disclosed in JP2017-37761A, WO2014-57633A, and the like, the method including: a step of mixing a metal salt with a reducing agent to obtain a complexing reaction solution; and a step of heating the complexing reaction solution to reduce metal ions in the complexing reaction solution and to obtain a slurry of metal nanoparticles.

In manufacturing the metal particle ink, a heat treatment may be performed such that the content of each component contained in the metal particle ink is adjusted to be in a predetermined range. The heat treatment may be performed under reduced pressure or under normal pressure. In a case in which the heat treatment is performed under normal pressure, the heat treatment may be performed in the atmospheric air or in an inert gas atmosphere.

### (Metal Complex Ink)

The metal complex ink is, for example, an ink composition obtained by dissolving a metal complex in a solvent.

### —Metal Complex—

Examples of metals constituting the metal complex include silver, copper, gold, aluminum, magnesium, tungsten, molybdenum, zinc, nickel, iron, platinum, tin, and lead. Among these, from the viewpoint of the electromagnetic wave-shielding properties, the metal constituting the metal complex preferably includes at least one selected from the group consisting of silver, gold, platinum, nickel, palladium, and copper, and more preferably includes silver.

The content of the metal contained in the metal complex ink is preferably 1% by mass to 40% by mass, more preferably 5% by mass to 30% by mass, and still more preferably 7% by mass to 20% by mass, with respect to the total amount of the metal complex ink, in terms of the metal element.

The metal complex can be obtained, for example, by reacting a metal salt with a complexing agent. Examples of a manufacturing method of the metal complex include a method of adding a metal salt and a complexing agent to a solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt include thiocyanate, sulfide, chloride, cyanide, cyanate, carbonate, nitrate, nitrite, sulfate, phosphate, perchlorate, tetrafluoroborate, an acetyl acetonate complex salt, and carboxylate.

From the viewpoint of the electromagnetic wave-shielding properties and storage stability, the metal salt is preferably a carboxylate.

The carboxylic acid forming the carboxylate is preferably at least one selected from the group consisting of carboxylic acids having 1 to 20 carbon atoms, and more preferably a carboxylic acid having 1 to 16 carbon atoms, and still more preferably a fatty acid having 2 to 12 carbon atoms.

The carboxylic acid forming the carboxylate may be a linear fatty acid or a branched fatty acid, and may have a substituent.

Examples of the linear fatty acid include formic acid, acetic acid, propionic acid, butyric acid, valeric acid, caproic acid, caprylic acid, pelargonic acid, capric acid, undecanoic acid, lauric acid, myristic acid, palmitic acid, stearic acid, palmitoleic acid, oleic acid, linoleic acid, and linolenic acid.

Examples of the branched fatty acid include isobutyric acid, isovaleric acid, 2-ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Examples of the carboxylic acid having a substituent include hexafluoroacetylacetonate, glycolic acid, lactic acid, 3-hydroxybutyric acid, 2-methyl-3-hydroxybutyric acid, 3-methoxybutyric acid, and acetoacetic acid.

The carboxylic acid forming the carboxylate may be a polyfunctional carboxylic acid.

Examples of the polyfunctional carboxylic acid include oxalic acid, succinic acid, glutaric acid, malonic acid, acetonedicarboxylic acid, 3-hydroxyglutaric acid, 2-methyl-3-hydroxyglutaric acid, and 2,2,4,4-hydroxyglutaric acid, and citric acid.

Among these metal salts, an alkyl carboxylate having 2 to 12 carbon atoms, oxalate, or acetoacetate is preferable, and an alkyl carboxylate having 2 to 12 carbon atoms is more preferable.

Examples of the complexing agent include an amine, an ammonium carbamate-based compound, an ammonium carbonate-based compound, an ammonium bicarbonate compound, and a carboxylic acid. Among these, from the viewpoint of the electromagnetic wave-shielding properties and stability of the metal complex, the complexing agent preferably includes at least one selected from the group consisting of an ammonium carbamate-based compound, an ammonium carbonate-based compound, and an amine.

The metal complex has a structure derived from a complexing agent, and preferably has a structure derived from at least one selected from the group consisting of an ammonium carbamate-based compound, an ammonium carbonate-based compound, an amine, and a carboxylic acid having 8 to 20 carbon atoms.

Examples of the amine as a complexing agent include ammonia, a primary amine, a secondary amine, a tertiary amine, and a polyamine.

Examples of the primary amine having a linear alkyl group include methylamine, ethylamine, n-propylamine, n-butylamine, n-pentylamine, n-hexylamine, n-heptylamine, n-octylamine, n-nonylamine, n-decylamine, n-undecylamine, n-dodecylamine, n-tridecylamine, n-tetradecylamine, n-pentadecylamine, n-hexadecylamine, n-heptadecylamine, and n-octadecylamine.

Examples of the primary amine having a branched alkyl group include isopropylamine, sec-butylamine, tert-butylamine, isopentylamine, 2-ethylhexylamine, and tert-octylamine.

Examples of the primary amine having an alicyclic structure include cyclopentylamine, cyclohexylamine, and dicyclohexylamine.

Examples of the primary amine having a hydroxyalkyl group include ethanolamine, propanolamine, and isopropanolamine.

Examples of the primary amine having an aromatic ring include benzylamine, aniline, N,N-dimethylaniline, and 4-aminopyridine.

Examples of the secondary amine include dimethylamine, diethylamine, dipropylamine, dibutylamine, diphenylamine, dicyclopentylamine, methylbutylamine, diethanolamine, N-methylethanolamine, dipropanolamine, and diisopropanolamine.

Examples of the tertiary amine include trimethylamine, triethylamine, tripropylamine, triethanolamine, tripropanolamine, triisopropanolamine, triphenylamine, N,N-dimethylaniline, N,N-dimethyl-p-toluidine, and 4-dimethylaminopyridine.

Examples of the polyamine include ethylenediamine, 1,2-diaminopropane, 1,3-diaminopropane, diethylenetriamine, triethylenetetramine, tetramethylenepentamine, hexamethylenediamine, tetraethylenepentamine, and a combination of these.

The amine is preferably an alkylamine, more preferably an alkylamine having 2 to 12 carbon atoms, and still more preferably a primary alkylamine having 2 to 8 carbon atoms.

The metal complex may be configured of one amine or two or more amines.

In reacting the metal salt with an amine, a ratio of the molar amount of the amine to a molar amount of the metal salt is preferably 1/1 to 15/1, and more preferably 1.5/1 to 6/1. In a case in which the above ratio is within the above range, the complex formation reaction is completed, and a transparent solution is obtained.

Examples of the ammonium carbamate-based compound as a complexing agent include ammonium carbamate, methylammonium methylcarbamate, ethylammonium ethylcarbamate, 1-propylammonium 1-propylcarbamate, isopropylammonium isopropylcarbamate, butylammonium butylcarbamate, isobutylammonium isobutylcarbamate, amylammonium amylcarbamate, hexylammonium hexylcarbamate, heptylammonium heptylcarbamate, octylammonium octylcarbamate, 2-ethylhexylammonium 2-ethylhexylcarbamate, nonylammonium nonylcarbamate, and decylammonium decylcarbamate.

Examples of the ammonium carbonate-based compound as a complexing agent include ammonium carbonate, methylammonium carbonate, ethylammonium carbonate, 1-propylammonium carbonate, isopropylammonium carbonate, butylammonium carbonate, isobutylammonium carbonate, amylammonium carbonate, hexylammonium carbonate, heptylammonium carbonate, octylammonium carbonate, 2-ethylhexylammonium carbonate, nonylammonium carbonate, and decylammonium carbonate.

Examples of the ammonium bicarbonate-based compound as a complexing agent include ammonium bicarbonate, methylammonium bicarbonate, ethylammonium bicarbonate, 1-propylammonium bicarbonate, isopropylammonium bicarbonate, butylammonium bicarbonate, isobutylammonium bicarbonate, amylammonium bicarbonate, hexylammonium bicarbonate, heptylammonium bicarbonate, octylammonium bicarbonate, 2-ethylhexylammonium bicarbonate, nonylammonium bicarbonate, and decylammonium bicarbonate.

In reacting the metal salt with an ammonium carbamate-based compound, an ammonium carbonate-based compound, or an ammonium bicarbonate-based compound, a ratio of a molar amount of the ammonium carbamate-based compound, the ammonium carbonate-based compound, or the ammonium bicarbonate-based compound to the molar amount of the metal salt is preferably 0.01/1 to 1/1, and more preferably 0.05/1 to 0.6/1.

The content of the metal complex i n the metal complex ink is preferably 10% by mass to 90% by mass, and more preferably 10% by mass to 40% by mass, with respect to the total amount of the metal complex ink. In a case in which the content of the metal complex is 10% by mass or more, the surface resistivity is further reduced. In a case in which the content of the metal complex is 90% by mass or less, jettability is improved in a case in which the metal complex ink is applied by using an ink jet recording method.

### —Solvent—

The metal complex ink preferably contains a solvent. The solvent is not particularly limited as long as it can dissolve the component contained in the metal complex ink, such as the metal complex. From the viewpoint of ease of manufacturing, a boiling point of the solvent is preferably 30° C. to 300° C., more preferably 50° C. to 200° C., and still more preferably 50° C. to 150° C.

The content of the solvent in the metal complex ink is preferably set such that the concentration of metal ions with respect to the metal complex (the amount of the metal present as free ions with respect to 1 g of the metal complex) is 0.01 mmol/g to 3.6 mmol/g, and more preferably set such that the concentration of metal ions is 0.05 mmol/g to 2 mmol/g. In a case in which the concentration of metal ions is within the above range, the metal complex ink has excellent fluidity and can obtain the electromagnetic wave-shielding properties.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water. The metal complex ink may contain only one solvent or two or more solvents.

The hydrocarbon is preferably a linear or branched hydrocarbon having 6 to 20 carbon atoms. Examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms. The cyclic hydrocarbons can include, for example, cyclohexane, cycloheptane, cyclooctane, cyclononane, cyclodecane, and decalin.

Examples of the aromatic hydrocarbon include benzene, toluene, xylene, and tetraline.

The ether may be any of a linear ether, a branched ether, or a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, or a tertiary alcohol.

Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, icosyl alcohol, and isoicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

### —Reducing Agent—

The metal complex ink may contain a reducing agent. In a case in which the metal complex ink contains a reducing agent, reduction of the metal complex into a metal is facilitated.

Examples of the reducing agent include a borohydride metal salt, an aluminum hydride salt, an amine, an alcohol, an aldehyde, an organic acid, reduced sugar, a sugar alcohol, sodium sulfite, a hydrazine compound, dextrin, hydroquinone, hydroxylamine, ethylene glycol, glutathione, and an oxime compound.

The reducing agent may be the oxime compound disclosed in JP2014-516463A. Examples of the oxime compound include acetone oxime, cyclohexanone oxime, 2-butanone oxime, 2,3-butanedione monoxime, dimethyl glyoxime, methyl acetoacetate monoxime, methyl pyruvate monoxime, benzaldehyde oxime, 1-indanone oxime, 2-adamantanone oxime, 2-methylbenzamide oxime, 3-methylbenzamide oxime, 4-methylbenzamide oxime, 3-aminobenzamide oxime, 4-aminobenzamide oxime, acetophenone oxime, benzamide oxime, and pinacolone oxime.

The metal complex ink may contain one reducing agent or two or more reducing agents.

The content of the reducing agent in the metal complex ink is not particularly limited, but is preferably 0.1% by mass to 20% by mass, more preferably 0.3% by mass to 10% by mass, and still more preferably 1% by mass to 5% by mass, with respect to the total amount of the metal complex ink.

### —Resin—

The metal complex ink may contain a resin. In a case in which the metal complex ink contains a resin, adhesiveness of the metal complex ink to the substrate is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

The metal complex ink may contain one resin or two or more resins.

### —Additive—

As long as the effects of the present disclosure are not reduced, the metal complex ink may further contain additives such as an inorganic salt, an organic salt, an inorganic oxide such as silica, a surface conditioner, a wetting agent, a crosslinking agent, an antioxidant, a rust inhibitor, a heat-resistant stabilizer, a surfactant, a plasticizer, a curing agent, a thickener, and a silane coupling agent. The total content of the additives in the metal complex ink is preferably 20% by mass or less with respect to the total amount of the metal complex ink.

The viscosity of the metal complex ink is not particularly limited. The viscosity of the metal complex ink need only be 0.001 Pa·s to 5000 Pa·s, and is preferably 0.001 Pa·s to 100 Pa·s. In a case in which the metal complex ink is applied by using a spray method or an ink jet recording method, the viscosity of the metal complex ink is preferably 1 mPa·s to 100 mPa·s, more preferably 2 mPa·s to 50 mPa·s, and still more preferably 3 mPa·s to 30 mPa·s.

The viscosity of the metal complex ink is a value measured at 25° C. by using a viscometer. The viscosity is measured using, for example, a VISCOMETER TV-22 type viscometer (manufactured by Toki Sangyo Co., Ltd.).

The surface tension of the metal complex ink is not particularly limited, and is preferably 20 mN/m to 45 mN/m and more preferably 25 mN/m to 35 mN/m. The surface tension is a value measured at 25° C. by using a surface tension meter.

The surface tension of the metal complex ink is measured using, for example, DY-700 (manufactured by Kyowa Interface Science Co., Ltd.).

### (Metal Salt Ink)

The metal salt ink is, for example, an ink composition obtained by dissolving a metal salt in a solvent.

### —Metal Salt—

Examples of metals constituting the metal salt include silver, copper, gold, aluminum, magnesium, tungsten, molybdenum, zinc, nickel, iron, platinum, tin, and lead. Among these, from the viewpoint of the electromagnetic wave-shielding properties, the metal constituting the metal salt preferably includes at least one selected from the group consisting of silver, gold, platinum, nickel, palladium, and copper, and more preferably includes silver.

The content of the metal contained in the metal salt ink is preferably 1% by mass to 40% by mass, more preferably 5% by mass to 30% by mass, and still more preferably 7% by mass to 20% by mass, with respect to the total amount of the metal salt ink, in terms of the metal element.

The content of the metal salt in the metal salt ink is preferably 10% by mass to 90% by mass, and more preferably 10% by mass to 40% by mass, with respect to the total amount of the metal salt ink. In a case in which the content of the metal salt is 10% by mass or more, the surface resistivity is further reduced. In a case in which the content of the metal salt is 90% by mass or less, jettability is improved in a case in which the metal particle ink is applied by using a spray method or an ink jet recording method.

Examples of the metal salt include benzoate, halide, carbonate, citrate, iodate, nitrite, nitrate, acetate, phosphate, sulfate, sulfide, trifluoroacetate, and carboxylate of a metal. Two or more salts may be combined.

From the viewpoint of the electromagnetic wave-shielding properties and storage stability, the metal salt is preferably a metal carboxylate. The carboxylic acid forming the carboxylate is preferably at least one selected from the group consisting of formic acid and a carboxylic acid having 1 to 30 carbon atoms, and more preferably a carboxylic acid having 8 to 20 carbon atoms, and still more preferably a fatty acid having 8 to 20 carbon atoms. The fatty acid may be linear or branched or may have a substituent.

Examples of the linear fatty acid include acetic acid, propionic acid, butyric acid, valeric acid, pentanoic acid, hexanoic acid, heptanoic acid, behenic acid, oleic acid, octanoic acid, nonanoic acid, decanoic acid, caproic acid, enanthic acid, caprylic acid, pelargonic acid, capric acid, and undecanoic acid.

Examples of the branched fatty acid include isobutyric acid, isovaleric acid, ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Examples of the carboxylic acid having a substituent include hexafluoroacetylacetonate, hydroangelate, 3-hydroxybutyric acid, 2-methyl-3-hydroxybutyric acid, 3-methoxybutyric acid, acetonedicarboxylic acid, 3-hydroxyglutaric acid, 2-methyl-3-hydroxyglutaric acid, and 2,2,4,4-hydroxyglutaric acid.

The metal salt may be a commercially available product or may be manufactured by a known method. A silver salt is manufactured, for example, by the following method.

First, a silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time by using an ultrasonic stirrer, and the formed precipitate is washed with ethanol and decanted. All of these steps can be performed at a room temperature (25° C.). A mixing ratio of the silver compound and the formic acid or fatty acid having 1 to 30 carbon atoms is preferably 1:2 to 2:1, and more preferably 1:1, in terms of molar ratio.

### —Solvent—

The metal salt ink preferably contains a solvent.

A type of the solvent is not particularly limited as long as it can dissolve the metal salt contained in the metal salt ink.

From the viewpoint of ease of manufacturing, the boiling point of the solvent is preferably 30° C. to 300° C., more preferably 50° C. to 300° C., and still more preferably 50° C. to 250° C.

The content of the solvent in the metal salt ink is preferably set such that the concentration of metal ions with respect to the metal salt (the amount of the metal present as free ions with respect to 1 g of the metal salt) is 0.01 mmol/g to 3.6 mmol/g, and more preferably set such that the concentration of metal ions is 0.05 mmol/g to 2.6 mmol/g. In a case in which the concentration of metal ions is within the above range, the metal salt ink has excellent fluidity and can obtain the electromagnetic wave-shielding properties.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water.

The metal salt ink may contain only one solvent or two or more solvents.

The solvent preferably contains an aromatic hydrocarbon.

Examples of the aromatic hydrocarbon include benzene, toluene, xylene, ethylbenzene, propylbenzene, isopropylbenzene, butylbenzene, isobutylbenzene, t-butylbenzene, trimethylbenzene, pentylbenzene, hexylbenzene, tetraline, benzyl alcohol, phenol, cresol, methyl benzoate, ethyl benzoate, propyl benzoate, and butyl benzoate.

From the viewpoint of compatibility with other components, the number of aromatic rings in the aromatic hydrocarbon is preferably 1 or 2, and more preferably 1.

From the viewpoint of ease of manufacturing, a boiling point of the aromatic hydrocarbon is preferably 50° C. to 300° C., more preferably 60° C. to 250° C., and still more preferably 80° C. to 200° C.

The solvent may contain an aromatic hydrocarbon and a hydrocarbon other than the aromatic hydrocarbon.

Examples of the hydrocarbon other than the aromatic hydrocarbon include a linear hydrocarbon having 6 to 20 carbon atoms, a branched hydrocarbon having 6 to 20 carbon atoms, and an alicyclic hydrocarbon having 6 to 20 carbon atoms.

Examples of the hydrocarbon other than the aromatic hydrocarbon include pentane, hexane, heptane, octane, nonane, decane, undecane, dodecane, tridecane, tetradecane, pentadecane, hexadecane, octadecane, nonadecane, decalin, cyclohexane, cycloheptane, cyclooctane, cyclononane, cyclodecane, decene, a terpene-based compound, and icosane.

The hydrocarbon other than the aromatic hydrocarbon preferably contains an unsaturated bond.

Examples of the hydrocarbon containing an unsaturated bond other than the aromatic hydrocarbon include a terpene-based compound.

Depending on the number of isoprene units constituting the terpene-based compound, the terpene-based compound is classified into, for example, a hemiterpene, a monoterpene, a sesquiterpene, a diterpene, a sesterterpene, a triterpene, a sesquarterpene, and a tetraterpene.

The terpene-based compound as the solvent may be any of the above compounds, but is preferably a monoterpene.

Examples of the monoterpene include pinene (α-pinene and β-pinene), terpineol (α-terpineol, β-terpineol, and γ-terpineol), myrcene, camphene, limonene (d-limonene, 1-limonene, and dipentene), ocimene (α-ocimene and β-ocimene), alloocimene, phellandrene (α-phellandrene and β-phellandrene), terpinene (α-terpinene and γ-terpinene), terpinolene (α-terpinolene, β-terpinolene, γ-terpinolene, and δ-terpinolene), 1,8-cineole, 1,4-cineole, sabinene, paramenthadiene, and carene (δ-3-carene).

As the monoterpene, a cyclic monoterpene is preferable, and pinene, terpineol, or carene is more preferable.

The ether may be any of a linear ether, a branched ether, or a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, or a tertiary alcohol.

Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, icosyl alcohol, and isoicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

The viscosity of the metal salt ink is not particularly limited. The viscosity of the metal salt ink need only be 0.01 Pa·s to 5000 Pa·s, and is preferably 0.1 Pa·s to 100 Pa·s. In a case in which the metal salt ink is applied by using a spray method or an ink jet recording method, the viscosity of the metal salt ink is preferably 1 mPa·s to 100 mPa·s, more preferably 2 mPa·s to 50 mPa·s, and still more preferably 3 mPa·s to 30 mPa·s.

The viscosity of the metal salt ink is a value measured at 25° C. by using a viscometer. The viscosity is measured using, for example, a VISCOMETER TV-22 type viscometer (manufactured by Toki Sangyo Co., Ltd.).

The surface tension of the metal salt ink is not particularly limited, and is preferably 20 mN/m to 45 mN/m and more preferably 25 mN/m to 35 mN/m. The surface tension is a value measured at 25° C. by using a surface tension meter.

The surface tension of the metal salt ink is measured using, for example, DY-700 (manufactured by Kyowa Interface Science Co., Ltd.).

The ink for forming an electromagnetic wave shielding layer preferably contains a metal complex or a metal salt.

The metal complex preferably has a structure derived from at least one selected from the group consisting of an ammonium carbamate-based compound, an ammonium carbonate-based compound, an amine, and a carboxylic acid having 8 to 20 carbon atoms.

The metal salt is preferably a metal carboxylate.

### <Method for Forming Electromagnetic Wave Shielding Layer>

In the second step, the electromagnetic wave shielding layer is preferably formed by applying the ink for forming an electromagnetic wave shielding layer into the ground region on the electronic substrate and solidifying the applied ink for forming an electromagnetic wave shielding layer through heating (for example, baking described below) and/or ultraviolet irradiation.

### (Application Method of Ink for Forming Electromagnetic Wave Shielding Layer)

As the application method of the ink for forming an electromagnetic wave shielding layer, an ink jet recording method, a dispenser method, or a spray method is preferable, and the ink jet recording method is particularly preferable.

The ink jet recording method may be any of an electric charge control method of jetting an ink by using electrostatic attraction force, a drop-on-demand method (pressure pulse method) using a vibration pressure of a piezo element, an acoustic ink jet method of jetting an ink by using a radiation pressure by means of converting electric signals into acoustic beams and irradiating the ink with the acoustic beams, or a thermal ink jet (Bubble Jet (registered trademark)) method of forming air bubbles by heating an ink and using the generated pressure.

As the ink jet recording method, particularly, an ink jet recording method, disclosed in JP1979-59936A (JP-S54-59936A), of jetting an ink from a nozzle using an action force caused by a rapid change in volume of the ink after being subjected to an action of thermal energy can be effectively used.

Regarding the ink jet recording method, the method disclosed in paragraphs 0093 to 0105 of JP2003-306623A can also be referred to.

Examples of ink jet heads used in the ink jet recording method include ink jet heads for a shuttle method of performing recording while scanning the heads in a width direction of the substrate using short serial heads and a line method using line heads each of which is formed of recording elements arranged for the entire region of one side of the substrate.

In the line method, by scanning the substrate to be scanned in a direction intersecting with the arrangement direction of the recording elements, a pattern can be formed on the entire surface of the substrate. Therefore, this method does not require a transport system such as a carriage that moves short heads for scanning.

In addition, complicated scanning control between the carriage movement and the substrate is not necessary, and only the substrate moves. Therefore, higher recording speeds can be realized compared to the shuttle method.

The amount of droplets of the insulating ink jetted from the ink jet head is preferably 1 pL (picoliter) to 100 pL, more preferably 3 pL to 80 pL, and still more preferably 3 pL to 20 pL.

A temperature of the electronic substrate in a case of applying the ink for forming an electromagnetic wave shielding layer is preferably 20° C. to 120° C., and more preferably 28° C. to 80° C.

From the viewpoint of the electromagnetic wave-shielding properties, the thickness of the whole electromagnetic wave shielding layer is preferably 0.1 μm to 30 μm, and more preferably 0.3 μm to 15 μm.

The thickness of the whole electromagnetic wave shielding layer is measured using a laser microscope (trade name “VK-X1000” manufactured by KEYENCE CORPORATION.).

An average thickness per electromagnetic wave shielding layer is obtained by dividing the thickness of the entire electromagnetic wave shielding layer by the number of times of the formation of the electromagnetic wave shielding layer (that is, the number of times of the application of the ink for forming an electromagnetic wave shielding layer).

In the second step, the average thickness per electromagnetic wave shielding layer is preferably 1.5 μm or less, and more preferably 1.2 μm or less.

In a case in which the average thickness per electromagnetic wave shielding layer is 1.5 μm or less, the electromagnetic wave-shielding properties are further improved.

In a lamination step, after a step of applying an ink for forming an electromagnetic wave shielding layer onto the electromagnetic wave shielding layer by using an ink jet recording method is executed a plurality of times, a step of irradiating the ink for forming an electromagnetic wave shielding layer applied onto the electromagnetic wave shielding layer with ultraviolet rays to further form an electromagnetic wave shielding layer may be executed.

From the viewpoint of image quality, electromagnetic wave-shielding properties, and adhesiveness, in a lamination step, it is preferable that after a step of applying an ink for forming an electromagnetic wave shielding layer onto the electromagnetic wave shielding layer by using an ink jet recording method is executed once, a step of irradiating the ink for forming an electromagnetic wave shielding layer applied onto the electromagnetic wave shielding layer with ultraviolet rays to further form an electromagnetic wave shielding layer is executed.

That is, it is preferable that the irradiation with ultraviolet rays is executed each time the step of applying the ink for forming an electromagnetic wave shielding layer is executed.

### (Baking Step)

The second step may include a baking step of baking the ink for forming an electromagnetic wave shielding layer applied onto the electronic substrate to solidify the ink for forming an electromagnetic wave shielding layer to form an electromagnetic wave shielding layer.

A baking temperature is preferably 250° C. or lower, more preferably 50° C. to 200° C., and still more preferably 60° C. to 180° C.

In addition, a baking time is preferably 1 minute to 120 minutes, and more preferably 1 minute to 40 minutes.

In a case in which the baking temperature and the baking time are in the above ranges, it is possible to reduce an influence of substrate deformation or the like caused by heat. In particular, in a case in which the ink for forming an electromagnetic wave shielding layer contains a metal salt or metal particles, it is preferable to bake the electromagnetic wave shielding layer after the ultraviolet irradiation.

### <Ink for Forming Insulating Protective Layer>

In the present disclosure, the internal insulating protective layer and the external insulating protective layer are each preferably a solidified product of the ink for forming an insulating protective layer.

That is, the internal insulating protective layer and the external insulating protective layer in the present disclosure are each preferably formed by applying the ink for forming an insulating protective layer and solidifying the ink for forming an insulating protective layer.

The ink for forming an insulating protective layer is preferably an active energy ray curable-type ink.

The ink for forming an insulating protective layer, which is the active energy ray curable-type ink, contains a polymerizable monomer and a polymerization initiator.

### (Polymerizable Monomer)

The polymerizable monomer refers to a monomer having at least one polymerizable group in one molecule.

In the present disclosure, the monomer refers to a compound having a molecular weight of 1000 or less. The molecular weight can be calculated from the type and number of atoms constituting the compound.

The polymerizable monomer may be a monofunctional polymerizable monomer having one polymerizable group or a polyfunctional polymerizable monomer having two or more polymerizable groups.

The polymerizable group in the polymerizable monomer may be a cationically polymerizable group or a radically polymerizable group.

From the viewpoint of curing properties, the radically polymerizable group is preferably an ethylenically unsaturated group.

From the viewpoint of curing properties, the cationically polymerizable group is preferably a group containing at least one of an oxirane ring or an oxetane ring.

### —Radically Polymerizable Monomer—

The radically polymerizable monomer (that is, the polymerizable monomer containing a radically polymerizable group) is preferably a monofunctional ethylenically unsaturated monomer from the viewpoint of curing properties.

Examples of the monofunctional ethylenically unsaturated monomer include monofunctional (meth)acrylate, monofunctional (meth)acrylamide, a monofunctional aromatic vinyl compound, monofunctional vinyl ether, and a monofunctional N-vinyl compound.

Examples of the monofunctional (meth)acrylate include methyl (meth)acrylate, ethyl (meth)acrylate, propyl (meth)acrylate, n-butyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, lauryl (meth)acrylate, stearyl (meth)acrylate, isostearyl (meth)acrylate, cyclohexyl (meth)acrylate, 4-n-butylcyclohexyl (meth)acrylate, 4-tert-butylcyclohexyl (meth)acrylate, bornyl (meth)acrylate, isobornyl (meth)acrylate, 2-ethylhexyldiglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, butoxymethyl (meth)acrylate, 3-methoxybutyl (meth)acrylate, 2-(2-methoxyethoxy)ethyl (meth)acrylate, 2-(2-butoxyethoxy)ethyl (meth)acrylate, 2,2,2-tetrafluoroethyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, 2-phenoxymethyl (meth)acrylate, 2-phenoxyethyl (meth)acrylate, glycidyl (meth)acrylate, glycidyloxybutyl (meth)acrylate, glycidyloxyethyl (meth)acrylate, glycidyloxypropyl (meth)acrylate, tetrahydrofurfuryl (meth)acrylate, 2-hydroxyethyl (meth)acrylate, 3-hydroxypropyl (meth)acrylate, 2-hydroxypropyl (meth)acrylate, 2-hydroxybutyl (meth)acrylate, 3-hydroxybutyl (meth)acrylate, 4-hydroxybutyl (meth)acrylate, cyclic trimethylolpropane formal (meth)acrylate, phenylglycidyl ether (meth)acrylate, dimethylaminoethyl (meth)acrylate, diethylaminoethyl (meth)acrylate, dimethylaminopropyl (meth)acrylate, diethylaminopropyl (meth)acrylate, trimethoxysilylpropyl (meth)acrylate, trimethylsilylpropyl (meth)acrylate, polyethylene oxide monomethyl ether (meth)acrylate, polyethylene oxide (meth)acrylate, polyethylene oxide monoalkyl ether (meth)acrylate, dipropylene glycol (meth)acrylate, polypropylene oxide monoalkyl ether (meth)acrylate, 2-methacryloyloxyethyl succinate, 2-methacryloyloxyhexahydrophthalic acid, 2-methacryloyloxyethyl-2-hydroxypropyl phthalate, ethoxydiethylene glycol (meth)acrylate, butoxydiethylene glycol (meth)acrylate, trifluoroethyl (meth)acrylate, perfluorooctylethyl (meth)acrylate, 2-hydroxy-3-phenoxypropyl (meth)acrylate, ethylene oxide (EO)-modified phenol (meth)acrylate, EO-modified cresol (meth)acrylate, EO-modified nonylphenol (meth)acrylate, propylene oxide (PO)-modified nonylphenol (meth)acrylate, EO-modified-2-ethylhexyl (meth)acrylate, dicyclopentenyl (meth)acrylate, dicyclopentenyloxyethyl (meth)acrylate, dicyclopentanyl (meth)acrylate, (3-ethyl-3-oxetanylmethyl) (meth)acrylate, phenoxyethylene glycol (meth)acrylate, 2-carboxyethyl (meth)acrylate, and 2-(meth)acryloyloxyethyl succinate.

Among these, from the viewpoint of improving heat resistance, the monofunctional (meth)acrylate is preferably a monofunctional (meth)acrylate having an aromatic ring or an aliphatic ring, and is more preferably isobornyl (meth)acrylate, 4-tert-butylcyclohexyl (meth)acrylate, dicyclopentenyl (meth)acrylate, or dicyclopentanyl (meth)acrylate.

Examples of the monofunctional (meth)acrylamide include (meth)acrylamide, N-methyl (meth)acrylamide, N-ethyl (meth)acrylamide, N-propyl (meth)acrylamide, N-n-butyl (meth)acrylamide, N-t-butyl (meth)acrylamide, N-butoxymethyl (meth)acrylamide, N-isopropyl (meth)acrylamide, N-methylol (meth)acrylamide, N,N-dimethyl (meth)acrylamide, N,N-diethyl (meth)acrylamide, and (meth)acryloylmorpholine.

Examples of the monofunctional aromatic vinyl compound include styrene, dimethylstyrene, trimethylstyrene, isopropylstyrene, chloromethylstyrene, methoxystyrene, acetoxystyrene, chlorostyrene, dichlorostyrene, bromostyrene, vinyl benzoic acid methyl ester, 3-methylstyrene, 4-methylstyrene, 3-ethylstyrene, 4-ethylstyrene, 3-propylstyrene, 4-propylstyrene, 3-butylstyrene, 4-butylstyrene, 3-hexylstyrene, 4-hexylstyrene, 3-octylstyrene, 4-octylstyrene, 3-(2-ethylhexyl)styrene, 4-(2-ethylhexyl)styrene, allyl styrene, isopropenyl styrene, butenyl styrene, octenyl styrene, 4-t-butoxycarbonyl styrene, and 4-t-butoxystyrene.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the monofunctional N-vinyl compound include N-vinyl-ε-caprolactam and N-vinylpyrrolidone.

The polyfunctional polymerizable monomer is not particularly limited as long as it is a monomer having two or more polymerizable groups. From the viewpoint of curing properties, the polyfunctional polymerizable monomer is preferably a polyfunctional radically polymerizable monomer, and more preferably a polyfunctional ethylenically unsaturated monomer.

Examples of the polyfunctional ethylenically unsaturated monomer include a polyfunctional (meth)acrylate compound and a polyfunctional vinyl ether.

Examples of the polyfunctional (meth)acrylate include ethylene glycol di(meth)acrylate, diethylene glycol di(meth)acrylate, triethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate, butylene glycol di(meth)acrylate, tetraethylene glycol di(meth)acrylate, neopentyl glycol di(meth)acrylate, 3-methyl-1,5-pentanediol di(meth)acrylate, 1,4-butanediol di(meth)acrylate, 1,6-hexanediol di(meth)acrylate, heptanediol di(meth)acrylate, EO-modified neopentyl glycol di(meth)acrylate, PO-modified neopentyl glycol di(meth)acrylate, EO-modified hexanediol di(meth)acrylate, PO-modified hexanediol di(meth)acrylate, octanediol di(meth)acrylate, nonanediol di(meth)acrylate, decanediol di(meth)acrylate, dodecanediol di(meth)acrylate, glycerin di(meth)acrylate, pentaerythritol di(meth)acrylate, ethylene glycol diglycidyl ether di(meth)acrylate, diethylene glycol diglycidyl ether di(meth)acrylate, tricyclodecanedimethanol di(meth)acrylate, trimethylolethane tri(meth)acrylate, trimethylolpropane tri(meth)acrylate, EO-added tri(meth)acrylate, pentaerythritol tri(meth)acrylate, trimethylolpropane pentaerythritol tetra(meth)acrylate, dipentaerythritol tetra(meth)acrylate, dipentaerythritol penta(meth)acrylate, dipentaerythritol hexa(meth)acrylate, tri(meth)acryloyloxyethoxytrimethylolpropane, glycerin polyglycidyl ether poly(meth)acrylate, and tris(2-acryloyloxyethyl) isocyanurate.

Examples of the polyfunctional vinyl ether include 1,4-butanediol divinyl ether, ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, 1,4-cyclohexanedimethanol divinyl ether, bisphenol A alkylene oxide divinyl ether, bisphenol F alkylene oxide divinyl ether, trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, EO-added trimethylolpropane trivinyl ether, PO-added trimethylolpropane trivinyl ether, EO-added ditrimethylolpropane tetravinyl ether, PO-added ditrimethylolpropane tetravinyl ether, EO-added pentaerythritol tetravinyl ether, PO-added pentaerythritol tetravinyl ether, EO-added dipentaerythritol hexavinyl ether, and PO-added dipentaerythritol hexavinyl ether.

### —Cationically Polymerizable Monomer—

As the cationically polymerizable monomer, a known cationically polymerizable monomer such as a compound (also referred to as an “oxirane compound” or an “epoxy compound”) having an oxirane ring (also referred to as an “epoxy ring”), a compound (also referred to as an “oxetane compound”) having an oxetane ring, and a vinyl ether compound can be used without particular limitation, from the viewpoint of curing properties.

The cationically polymerizable monomer is not particularly limited as long as it is a compound that initiates a polymerization reaction with cationic polymerization initiating species generated from a photocationic polymerization initiator described below and is cured, and various known cationically polymerizable monomers known as a photocationically polymerizable monomer can be used.

Examples of the cationically polymerizable monomer include an epoxy compound, a vinyl ether compound, and an oxetane compound, which are disclosed in JP1994-9714A (JP-H6-9714A), JP2001-31892A, JP2001-40068A, JP2001-55507A, JP2001-310938A, JP2001-310937A, and JP2001-220526A.

In addition, as the cationically polymerizable monomer, for example, a cationic polymerization-based photocurable resin is known, and recently, a photocationic polymerization-based photocurable resin sensitized in a visible light wavelength of 400 nm or more has been disclosed, for example, in JP1994-43633A (JP-H6-43633A) and JP1996-324137A (JP-H8-324137A).

Examples of the epoxy compound include aromatic epoxides, alicyclic epoxides, and aliphatic epoxides.

Examples of the aromatic epoxide include di or polyglycidyl ether produced by reacting a polyhydric phenol having at least one aromatic nucleus or an alkylene oxide adduct thereof with epichlorohydrin.

Examples of the aromatic epoxide include di or polyglycidyl ethers of bisphenol A or an alkylene oxide adduct of bisphenol A, di or polyglycidyl ethers of hydrogenated bisphenol A or an alkylene oxide adduct of hydrogenated bisphenol A, and novolak-type epoxy resin. Here, examples of the alkylene oxide include ethylene oxide and propylene oxide.

Examples of the alicyclic epoxide preferably include cyclohexene oxide or cyclopentene oxide-containing compounds, which are obtained by epoxidizing a compound having at least one cycloalkane ring such as a cyclohexene ring and a cyclopentene ring with an appropriate oxidizing agent such as hydrogen peroxide and peroxy acid.

Examples of the aliphatic epoxide include aliphatic polyhydric alcohols or di- or polyglycidyl ethers of an alkylene oxide adduct of polyhydric alcohol, and typical examples thereof include diglycidyl ethers of alkylene glycol, such as diglycidyl ether of ethylene glycol, diglycidyl ether of propylene glycol, and diglycidyl ether of 1,6-hexanediol; polyglycidyl ethers of polyhydric alcohol, such as di- or triglycidyl ether of glycerin or an alkylene oxide adduct of glycerin; and diglycidyl ethers of polyalkylene glycol represented by diglycidyl ether of polyethylene glycol or an alkylene oxide adduct of polyethylene glycol, and diglycidyl ether of polypropylene glycol or an alkylene oxide adduct of polypropylene glycol.

Here, examples of the alkylene oxide include ethylene oxide and propylene oxide.

Hereinafter, the monofunctional and polyfunctional epoxy compounds will be described in detail.

Examples of the monofunctional epoxy compound include phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2-epoxydodecane, epichlorohydrin, 1,2-epoxydecane, styrene oxide, cyclohexene oxide, 3-methacryloyloxymethylcyclohexene oxide, 3-acryloyloxymethylcyclohexene oxide, 3-vinylcyclohexene oxide, and 4-vinylcyclohexene oxide.

Examples of the polyfunctional epoxy compound include bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, an epoxy novolac resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexanecarboxylate, 2-(3,4-epoxycyclohexyl-5,5-spiro-3,4-epoxy)cyclohexane-meta-dioxane, bis(3,4-epoxycyclohexylmethyl)adipate, bis(3,4-epoxy-6-methylcyclohexylmethyl)adipate, 3,4-epoxy-6-methylcyclohexyl-3′,4′-epoxy-6′-methylenebis(3,4-epoxycyclohexane), dicyclopentadiene methylcyclohexanecarboxylate, diepoxide, ethylene glycol di(3,4-epoxycyclohexylmethyl) ether, ethylene bis(3,4-epoxycyclohexanecarboxylate), dioctyl epoxyhexahydrophthalate, di-2-ethylhexyl epoxyhexahydrophthalate, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers, 1,13-tetradecadiene dioxide, limonene dioxide, 1,2,7,8-diepoxyoctane, and 1,2,5,6-diepoxycyclooctane.

Among the epoxy compounds, an aromatic epoxide and an alicyclic epoxide are preferable from the viewpoint of an excellent curing rate, and an alicyclic epoxide is particularly preferable.

The oxetane compound refers to a compound having at least one oxetane ring, and any known oxetane compound as disclosed in JP2001-220526A, JP2001-310937A, or JP2003-341217A can be selected and used.

As the compound having an oxetane ring, a compound having 1 to 4 oxetane rings in a structure thereof is preferable. By using such a compound, it is easy to maintain the viscosity of the ink composition within a favorable range of handleability. In addition, high adhesiveness of the cured ink composition to a recording medium can be obtained.

Examples of the compound having 1 or 2 oxetane rings in a molecule include compounds represented by Formulae (1) to (3).

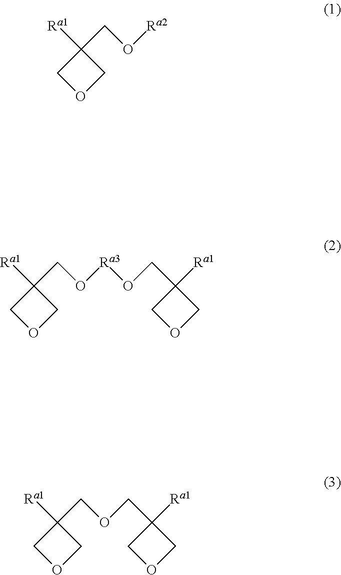

In Formulae (1) to (3), R^{a1} represents a hydrogen atom, an alkyl group having 1 to 6 carbon atoms, a fluoroalkyl group having 1 to 6 carbon atoms, an allyl group, an aryl group, a furyl group, or a thienyl group.

In a case in which two R^{a1}'s exist in a molecule, they may be the same as or different from each other.

Examples of the alkyl group include a methyl group, an ethyl group, a propyl group, and a butyl group, and preferred examples of the fluoroalkyl group include one of the alkyl groups of which one hydrogen is substituted with a fluorine atom.

R^{a2} represents a hydrogen atom, an alkyl group having 1 to 6 carbon atoms, an alkenyl group having 2 to 6 carbon atoms, a group having an aromatic ring, an alkylcarbonyl group having 2 to 6 carbon atoms, an alkoxycarbonyl group having 2 to 6 carbon atoms, and an N-alkylcarbamoyl group having 2 to 6 carbon atoms.

Examples of the alkyl group include a methyl group, an ethyl group, a propyl group, and a butyl group. Examples of the alkenyl group include a 1-propenyl group, a 2-propenyl group, a 2-methyl-1-propenyl group, a 2-methyl-2-propenyl group, a 1-butenyl group, a 2-butenyl group, and a 3-butenyl group. Examples of the group having an aromatic ring include a phenyl group, a benzyl group, a fluorobenzyl group, a methoxybenzyl group, and a phenoxyethyl group. Examples of the alkylcarbonyl group include an ethylcarbonyl group, a propylcarbonyl group, and a butylcarbonyl group. Examples of the alkoxycarbonyl group include an ethoxycarbonyl group, a propoxycarbonyl group, and a butoxycarbonyl group. Examples of the N-alkylcarbamoyl group include an ethylcarbamoyl group, a propylcarbamoyl group, a butylcarbamoyl group, a pentylcarbamoyl group.

R^{a2} may have a substituent, and examples of the substituent include an alkyl group having 1 to 6 carbon atoms and a fluorine atom.

R^{a3} represents a linear or branched alkylene group, a linear or branched poly(alkyleneoxy) group, a linear or branched unsaturated hydrocarbon group, a carbonyl group or a carbonyl group-containing alkylene group, a carboxy group-containing alkylene group, a carbamoyl group-containing alkylene group, or a group shown below. Examples of the alkylene group include an ethylene group, a propylene group, and a butylene group. Examples of the poly(alkyleneoxy) group include a poly(ethyleneoxy) group and a poly(propyleneoxy) group. Examples of the unsaturated hydrocarbon group include a propenylene group, a methylpropenylene group, and a butenylene group.

Examples of the compound represented by Formula (1) include 3-ethyl-3-hydroxymethyloxetane (OXT-101: manufactured by Toagosei Co., Ltd.), 3-ethyl-3-(2-ethylhexyloxymethyl)oxetane (OXT-212: manufactured by Toagosei Co., Ltd.), and 3-ethyl-3-phenoxymethyloxetane (OXT-211: manufactured by Toagosei Co., Ltd.).

Examples of the compound represented by Formula (2) include 1,4-bis[(3-ethyl-3-oxetanylmethoxy)methyl]benzene (OXT-121: manufactured by Toagosei Co., Ltd.).

Examples of the compound represented by Formula (3) include bis(3-ethyl-3-oxetanylmethyl) ether (OXT-221: manufactured by Toagosei Co., Ltd.).

For the compound having an oxetane ring, paragraphs 0021 to 0084 of JP2003-341217A, JP2004-91556A, and paragraphs 0022 to 0058 of JP2004-91556A may be referred to.

Examples of a preferred cationically polymerizable monomer are listed below.

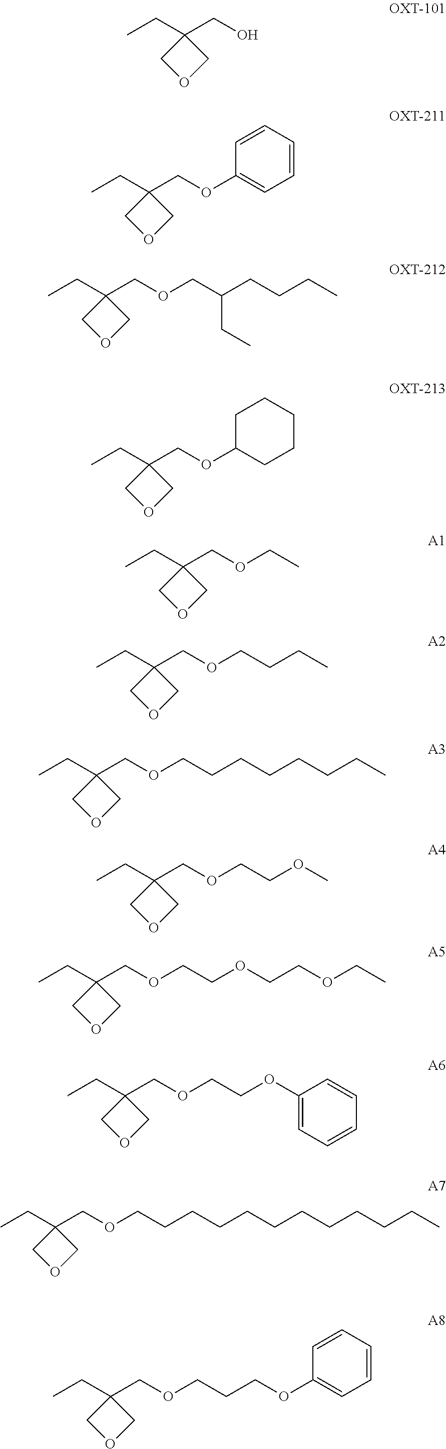

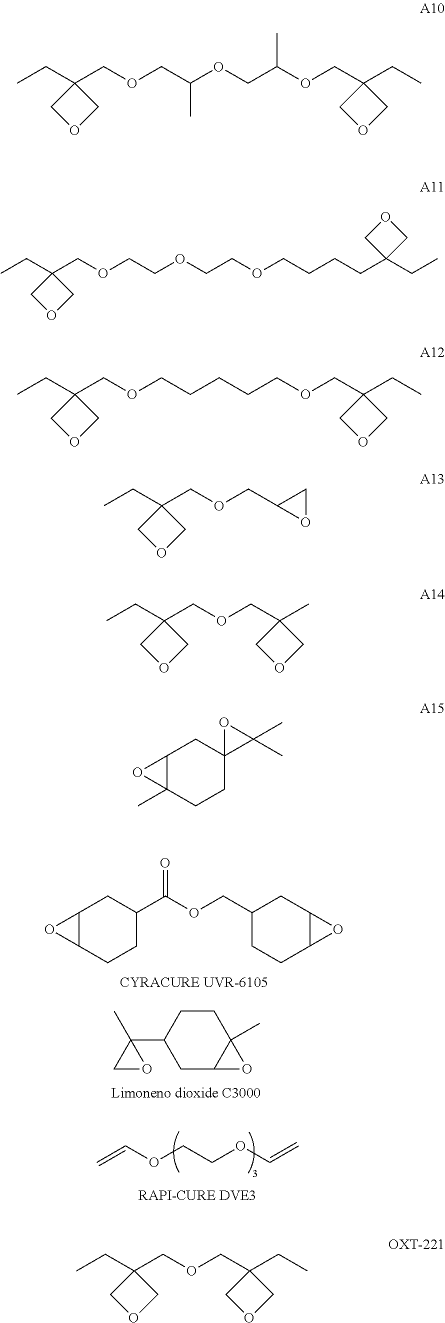

Examples of the cationically polymerizable monomer also include a vinyl ether compound.

Examples of the vinyl ether compound include di- or trivinyl ether compounds such as ethylene glycol divinyl ether, diethylene glycol divinyl ether, triethylene glycol divinyl ether, propylene glycol divinyl ether, dipropylene glycol divinyl ether, butanediol divinyl ether, hexanediol divinyl ether, cyclohexanedimethanol divinyl ether, and trimethylolpropane trivinyl ether; and mono-vinyl ether compounds such as ethyl vinyl ether, n-butyl vinyl ether, isobutyl vinyl ether, octadecyl vinyl ether, cyclohexyl vinyl ether, hydroxybutyl vinyl ether, 2-ethylhexyl vinyl ether, cyclohexanedimethanol monovinyl ether, n-propyl vinyl ether, isopropyl vinyl ether, isopropenyl vinyl ether, dodecyl vinyl ether, diethylene glycol monovinyl ether, and octadecyl vinyl ether.

The monofunctional vinyl ether and the polyfunctional vinyl ether will be exemplified below in detail.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the polyfunctional vinyl ether include divinyl ethers such as ethylene glycol divinyl ether, diethylene glycol divinyl ether, polyethylene glycol divinyl ether, propylene glycol divinyl ether, butylene glycol divinyl ether, hexanediol divinyl ether, bisphenol A alkylene oxide divinyl ether, and bisphenol F alkylene oxide divinyl ether; and polyfunctional vinyl ethers such as trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, ethylene oxide-added trimethylolpropane trivinyl ether, propylene oxide-added trimethylolpropane trivinyl ether, ethylene oxide-added ditrimethylolpropane tetravinyl ether, propylene oxide-added ditrimethylolpropane tetravinyl ether, ethylene oxide-added pentaerythritol tetravinyl ether, propylene oxide-added pentaerythritol tetravinyl ether, ethylene oxide-added dipentaerythritol hexavinyl ether, and propylene oxide-added dipentaerythritol hexavinyl ether.

As the vinyl ether compound, from the viewpoint of curing properties, adhesiveness to the recording medium, surface hardness of the formed image, and the like, a di- or trivinyl ether compound is preferable, and a divinyl ether compound is particularly preferable.

The content of the polymerizable monomer is preferably 10% by mass to 98% by mass, and more preferably 50% by mass to 98% by mass, with respect to the total amount of the ink for forming an insulating protective layer.

### (Polymerization Initiator)

The ink for forming an insulating protective layer may contain a polymerization initiator for the purpose of curing the polymerizable monomer. As the polymerization initiator, a suitable polymerization initiator can be selected from a radical polymerization initiator or a cationic polymerization initiator depending on a type of the polymerizable monomers.

Examples of the polymerization initiator include an oxime compound, an alkylphenone compound, an acylphosphine compound, an aromatic onium salt compound, an organic peroxide, a thio compound, a hexaarylbisimidazole compound, a borate compound, an azinium compound, a titanocene compound, an active ester compound, a carbon halogen bond-containing compound, and an alkylamine.

From the viewpoint of further improving conductivity, the radical polymerization initiator is preferably at least one selected from the group consisting of an oxime compound, an alkylphenone compound, and a titanocene compound, more preferably an alkylphenone compound, and still more preferably at least one selected from the group consisting of an α-aminoalkylphenone compound a benzyl ketal and, an alkylphenone.

As the cationic polymerization initiator, a photoacid generator is preferable.

As the photoacid generator, for example, a compound used for a chemically amplified photoresist or photocationic polymerization is used (refer to “Organic Material for Imaging” edited by The Organic Electronics Materials Research Association, Bun-shin Publication (1993), 187 to 192 pages). Among these, an aromatic onium salt compound is preferable, an onium salt compound such as a diazonium salt, a phosphonium salt, a sulfonium salt, or an iodonium salt is more preferable, and a sulfonium salt or an iodonium salt is still more preferable.

The content of the polymerization initiator is preferably 0.5% by mass to 20% by mass, and more preferably 2% by mass to 10% by mass, with respect to the total amount of the ink for forming an insulating layer.

The ink for forming an insulating protective layer may contain other components different from the polymerization initiator and the polymerizable monomer. Examples of the other components include a chain transfer agent, a polymerization inhibitor, a sensitizer, a surfactant, and an additive.

### (Chain Transfer Agent)

The ink for forming an insulating protective layer may contain at least one chain transfer agent.

From the viewpoint of improving reactivity of photopolymerization reaction, the chain transfer agent is preferably a polyfunctional thiol.

Examples of the polyfunctional thiol include aliphatic thiols such as hexane-1,6-dithiol, decane-1,10-dithiol, dimercaptodiethyl ether, and dimercaptodiethyl sulfide, aromatic thiols such as xylylene dimercaptan, 4,4′-dimercaptodiphenylsulfide, and 1,4-benzenedithiol; poly(mercaptoacetate) of a polyhydric alcohol such as ethylene glycol bis(mercaptoacetate), polyethylene glycol bis(mercaptoacetate), propylene glycol bis(mercaptoacetate), glycerin tris(mercaptoacetate), trimethylolethane tris(mercaptoacetate), trimethylolpropane tris(mercaptoacetate), pentaerythritol tetrakis(mercaptoacetate), and dipentaerythritol hexakis(mercaptoacetate); poly(3-mercaptopropionate) of a polyhydric alcohol such as ethylene glycol bis(3-mercaptopropionate), polyethylene glycol bis(3-mercaptopropionate), propylene glycol bis(3-mercaptopropionate), glycerin tris(3-mercaptopropionate), trimethylolethane tris(mercaptopropionate), trimethylolpropane tris(3-mercaptopropionate), pentaerythritol tetrakis(3-mercaptopropionate), and dipentaerythritol hexakis(3-mercaptopropionate); and poly(mercaptobutyrate) such as 1,4-bis(3-mercaptobutyryloxy)butane, 1,3,5-tris(3-mercaptobutyloxyethyl)-1,3,5-triazine-2,4,6(1H,3H,5H)-trione, and pentaerythritol tetrakis(3-mercaptobutyrate).

### (Polymerization Inhibitor)

The ink for forming an insulating protective layer may contain at least one polymerization inhibitor.

Examples of the polymerization inhibitor include p-methoxyphenol, quinones (for example, hydroquinone, benzoquinone, and methoxybenzoquinone), phenothiazine, catechols, alkylphenols (for example, dibutyl hydroxy toluene (BHT)), alkyl bisphenols, zinc dimethyldithiocarbamate, copper dimethyldithiocarbamate, copper dibutyldithiocarbamate, copper salicylate, thiodipropionic acid esters, mercaptobenzimidazole, phosphites, 2,2,6,6-tetramethylpiperidine-1-oxyl (TEMPO), 2,2,6,6-tetramethyl-4-hydroxypiperidine-1-oxyl (TEMPOL), and tris(N-nitroso-N-phenylhydroxylamine)aluminum salt (also known as Cupferron A1).

Among these, as the polymerization inhibitor, at least one selected from p-methoxyphenol, catechols, quinones, alkylphenols, TEMPO, TEMPOL, and tris(N-nitroso-N-phenylhydroxylamine)aluminum salt is preferable, and at least one selected from p-methoxyphenol, hydroquinone, benzoquinone, BHT, TEMPO, TEMPOL, and tris(N-nitroso-N-phenylhydroxylamine)aluminum salt is more preferable.

In a case in which the ink for forming an insulating protective layer contains a polymerization inhibitor, the content of the polymerization inhibitor is preferably 0.01% by mass to 2.0% by mass, more preferably 0.02% by mass to 1.0% by mass, and particularly preferably 0.03% by mass to 0.5% by mass, with respect to the total amount of the ink for forming an insulating protective layer.

### (Sensitizer)

The ink for forming an insulating protective layer may contain at least one sensitizer.

Examples of the sensitizer include a polynuclear aromatic compound (for example, pyrene, perylene, triphenylene, and 2-ethyl-9,10-dimethoxyanthracene), a xanthene-based compound (for example, fluorescein, eosin, erythrosin, rhodamine B, and rose bengal), a cyanine-based compound (for example, thiacarbocyanine and oxacarbocyanine), a merocyanine-based compound (for example, merocyanine and carbomerocyanine), a thiazine-based compound (for example, thionine, methylene blue, and toluidine blue), an acridine-based compound (for example, acridine orange, chloroflavine, and acryflavine), anthraquinones (for example, anthraquinone), a squarylium-based compound (for example, squarylium), a coumarin-based compound (for example, 7-diethylamino-4-methylcoumarin), a thioxanthone-based compound (for example, isopropylthioxanthone), and a thiochromanone-based compound (for example, thiochromanone). Among these, the sensitizer is preferably a thioxanthone-based compound.

In a case in which the ink for forming an insulating protective layer contains a sensitizer, the content of the sensitizer is not particularly limited, but is preferably 1.0% by mass to 15.0% by mass, and more preferably 1.5% by mass to 5.0% by mass, with respect to the total amount of the ink for forming an insulating protective layer.

### (Surfactant)

The ink for forming an insulating protective layer may contain at least one surfactant.

Examples of the surfactant include surfactants disclosed in JP1987-173463A (JP-S62-173463A) and JP1987-183457A (JP-S62-183457A). In addition, examples of the surfactant include anionic surfactants such as dialkyl sulfosuccinate, alkyl naphthalene sulfonate, and a fatty acid salt; nonionic surfactants such as polyoxyethylene alkyl ether, polyoxyethylene alkyl allyl ether, acetylene glycol, and a polyoxyethylene-polyoxypropylene block copolymer; and cationic surfactants such as an alkylamine salt and a quaternary ammonium salt. In addition, the surfactant may be a fluorine-based surfactant or a silicone-based surfactant.

In a case in which the ink for forming an insulating protective layer contains a surfactant, the content of the surfactant is preferably 0.5% by mass or less, and more preferably 0.1% by mass or less, with respect to the total amount of the ink for forming an insulating protective layer. A lower limit of the content of the surfactant is not particularly limited.

In a case in which the content of the surfactant is 0.5% by mass or less, the ink for forming an insulating protective layer is difficult to spread after being applied. Therefore, an outflow of the ink for forming an insulating protective layer is suppressed, thus improving the electromagnetic wave-shielding properties.

### (Organic Solvent)

The ink for forming an insulating protective layer may contain at least one organic solvent.

Examples of the organic solvent include (poly)alkylene glycol monoalkyl ethers such as ethylene glycol monoethyl ether, diethylene glycol monoethyl ether, triethylene glycol monomethyl ether, propylene glycol monomethyl ether (PGME), dipropylene glycol monomethyl ether, and tripropylene glycol monomethyl ether; (poly)alkylene glycol dialkyl ethers such as ethylene glycol dibutyl ether, diethylene glycol dimethyl ether, diethylene glycol diethyl ether, dipropylene glycol diethyl ether, and tetraethylene glycol dimethyl ether; (poly)alkylene glycol acetates such as diethylene glycol acetate; (poly)alkylene glycol diacetates such as ethylene glycol diacetate and propylene glycol diacetate; (poly)alkylene glycol monoalkyl ether acetates such as ethylene glycol monobutyl ether acetate and propylene glycol monomethyl ether acetate, ketones such as methyl ethyl ketone and cyclohexanone; lactones such as γ-butyrolactone; esters such as ethyl acetate, propyl acetate, butyl acetate, 3-methoxybutyl acetate (MBA), methyl propionate, and ethyl propionate; cyclic ethers such as tetrahydrofuran and dioxane; and amides such as dimethylformamide and dimethylacetamide.

In a case in which the ink for forming an insulating protective layer contains an organic solvent, the content of the organic solvent is preferably 70% by mass or less, and more preferably 50% by mass or less, with respect to the total amount of the ink for forming an insulating protective layer. A lower limit of the content of the organic solvent is not particularly limited.

### (Additive)

As necessary, the ink for forming an insulating protective layer may contain an additive such as a co-sensitizer, an ultraviolet absorber, an antioxidant, an antifading agent, and a basic compound.

### (Physical Properties)

From the viewpoint of improving jetting stability in a case in which the ink for forming an insulating protective layer is applied by using an ink jet recording method, a pH of the ink for forming an insulating protective layer is preferably 7 to 10, and more preferably 7.5 to 9.5. The pH is measured at 25° C. using a pH meter, such as a pH meter (model number “HM-31”) manufactured by DKK-Toa Corporation.

The viscosity of the ink for forming an insulating protective layer is preferably 0.5 mPa·s to 60 mPa·s, and more preferably 2 mPa·s to 40 mPa·s. The viscosity is measured at 25° C. using a viscometer, such as a TV-22 type viscometer manufactured by Toki Sangyo Co., Ltd.

The surface tension of the ink for forming an insulating protective layer is preferably 60 mN/m or less, more preferably 20 mN/m to 50 mN/m, and still more preferably 25 mN/m to 45 mN/m. The surface tension is measured at 25° C. using a surface tension meter, for example, by a plate method using an automatic surface tension meter (trade name, “CBVP-Z”) manufactured by Kyowa Interface Science Co., Ltd.

### <Method for Forming Insulating Protective Layer>

In the first step, it is preferable that the ink for forming an insulating protective layer is applied onto an electronic substrate by using an ink jet recording method, a dispenser coating method, or a spray coating method and the ink for forming an insulating protective layer is cured, to form an insulating protective layer.

From the viewpoint of making it possible to form a thin ink film by applying once a small amount of droplets by means of jetting, it is preferable that the ink for forming an insulating protective layer is applied by an ink jet recording method. Details of the ink jet recording method are as described above.

A method of curing the ink for forming an insulating protective layer is not particularly limited, and examples thereof include a method of irradiating the ink for forming an insulating protective layer applied onto the substrate with an active energy ray.

Examples of the active energy ray include ultraviolet rays, visible rays, and electron beams. Among these, ultraviolet rays (hereinafter, also referred to as “UV”) are preferable.

A peak wavelength of the ultraviolet rays is preferably 200 nm to 405 nm, more preferably 250 nm to 400 nm, and still more preferably 300 nm to 400 nm.

An exposure amount during the irradiation with an active energy ray is preferably 100 mJ/cm² to 5000 mJ/cm², and more preferably 300 mJ/cm² to 1500 mJ/cm².

As a light source for ultraviolet irradiation, a mercury lamp, a gas laser, and a solid-state laser are mainly used, and a mercury lamp, a metal halide lamp, and an ultraviolet fluorescent lamp are widely known. In addition, a light emitting diode (UV-LED) and a laser diode (UV-LD) are compact, long-life, highly efficient, and low-cost, and are expected to be used as the light source for ultraviolet irradiation. Among these, the light source for ultraviolet irradiation is preferably a metal halide lamp, a high-pressure mercury lamp, a medium-pressure mercury lamp, a low-pressure mercury lamp, or UV-LED.

In the step of obtaining the insulating protective layer, in order to obtain an insulating protective layer having a desired thickness, the step of applying the insulating ink and irradiating the insulating ink with an active energy ray is preferably repeated two or more times.

A thickness of the insulating protective layer is preferably 5 μm to 5000 μm, and more preferably 10 μm to 2000 μm.

### EXAMPLES

Hereinafter, examples of the present disclosure will be shown, but the present disclosure is not limited to the following examples.

### Example 1

### <Manufacture of Electronic Device X1>

### (Preparation of Electronic Substrate B1)

The shielding can and the frame were removed from the LTE module manufactured by Quectel, Inc. to obtain an electronic substrate B1.

This electronic substrate B1 is included in the scope of the electronic substrate (that is, the electronic substrate comprising the wiring board having the mounting surface, the ground electrode that defines the ground region on the mounting surface, the electronic component that is located on the mounting surface and is disposed in the ground region, and the adjacent conductive component that is disposed adjacent to the outer edge of the ground electrode and is electrically insulated from the ground electrode) in the present disclosure.

In the electronic substrate B1, the height of the electronic component in the ground region, the closest distance between the outer edge of the ground electrode and the edge of the adjacent conductive component (hereinafter, also referred to as a “distance between the ground electrode and the adjacent conductive component”), and the height of the adjacent conductive component are as shown in Table 1.

The ground electrode has a height of 25 μm and a width of 900 μm.

The height is a height from the mounting surface (surface of the solder resist layer) of the wiring board.

### (Preparation of Ink A1 for Forming Insulating Protective Layer)

The components of the following composition were mixed together, and the mixture was stirred for 20 minutes at 25° C. under a condition of 5000 rpm by using a mixer (trade name “L4R” manufactured by Silverson), thereby obtaining an ink A1 for forming an insulating protective layer.

### —Composition of Ink A1 for Forming Insulating Protective Layer—

Omni. 379: 2-(dimethylamino)-2-(4-methylbenzyl)-1-(4-morpholinophenyl)-butan-1-one (trade name “Omnirad 379” manufactured by IGM Resins B.V., Inc.) . . . 1.0% by mass
4-PBZ: 4-phenylbenzophenone (trade name “Omnirad 4-PBZ” manufactured by IGM Resins B. V.) . . . 7.5% by mass
NVC: N-vinylcaprolactam (manufactured by FUJIFILM Wako Pure Chemical Corporation) . . . 15.0% by mass
HDDA: 1,6-hexanediol diacrylate (trade name “SR238” manufactured by Sartomer Japan Inc.) . . . 25.5% by mass
IBOA: isobornyl acrylate (trade name “SR506” manufactured by Sartomer Japan Inc.) . . . 30.0% by mass
Pentaerythritol tetrakis(3-mercaptobutyrate) trade name “KARENZ MT-PE1” 20.0% by mass
MEHQ: p-methoxyphenol (manufactured by FUJIFILM Wako Pure Chemical Corporation) . . . 1.0% by mass

### (Ink C1 for Forming Electromagnetic Wave Shielding Layer)

40 g of silver neodecanoate was added to a 200 mL three-neck flask. Next, 30.0 g of trimethylbenzene and 30.0 g of terpineol were added thereto and stirred, thereby obtaining a solution containing a silver salt. The obtained solution was filtered using a membrane filter made of polytetrafluoroethylene (PTFE) having a pore diameter of 0.45 μm, thereby obtaining an ink C1 for forming an electromagnetic wave shielding layer.

### (Formation of Internal Insulating Protective Layer and External Insulating Protective Layer (First Step))

An ink jet recording device (trade name “DMP-2850” manufactured by Fujifilm Dimatix Inc.) was prepared, and an ink cartridge (10 picoliters) of this ink jet recording device was filled with the ink B1 for forming an insulating protective layer.

UV SPOT CURE OmniCure S2000 (manufactured by Lumen Dynamics Group Inc.) was disposed next to the ink jet head of the ink jet recording device.

The ink A1 for forming an insulating protective layer was jetted from the ink jet head in the ink jet recording device and applied to a formation region of the insulating protective layer on the electronic substrate, and the applied ink A1 for forming an insulating protective layer was irradiated with ultraviolet rays (UV) by UV spot curing. By repeating a set of the application of the ink and UV irradiation, an insulating protective layer was formed.

A pattern of the insulating protective layer was set such that it covers the electronic component in the ground region of the electronic substrate B1 and a pattern edge is located inside an inner edge of the ground electrode (for example, see FIG. 2A). A repetition number of a set of the application of the ink and the UV irradiation was adjusted such that the thickness T2 (unit: μm) of the internal insulating protective layer on the electronic component in the ground region is a value shown in Table 1.

Similarly, the ink A1 for forming an insulating protective layer was jetted from the ink jet head in the ink jet recording device and applied to a formation region of the external insulating protective layer on the electronic substrate (note: a pattern of the external insulating protective layer will be described below), and the applied ink A1 for forming an insulating protective layer was irradiated with ultraviolet rays (UV) by UV spot curing. By repeating a set of the application of the ink and UV irradiation, an external insulating protective layer was formed.

The pattern of the external insulating protective layer was set such that it extends over the plurality of adjacent conductive components and covers the plurality of adjacent conductive components (for example, see FIG. 2A). A repetition number of a set of the application of the ink and the UV irradiation was adjusted such that the thickness T1 (unit: μm) of the external insulating protective layer on the adjacent conductive component is a value shown in Table 1.

Application conditions of the ink A1 for forming an insulating protective layer in the formation of the internal insulating protective layer and the formation of the external insulating protective layer were set to conditions in which a resolution is 1270 dots per inch (dpi) and the amount of droplets is 10 picoliters per dot.

### (Formation of Electromagnetic Wave Shielding Layer (Second Step))

An ink jet recording device (trade name “DMP-2850” manufactured by Fujifilm Dimatix Inc.) was prepared, and an ink cartridge (10 picoliters) of this ink jet recording device was filled with the ink C1 for forming an electromagnetic wave shielding layer.

Next, the electron substrate on which the internal insulating protective layer and the external insulating protective layer were formed was heated to 60° C.

Next, the ink C1 for forming an electromagnetic wave shielding layer was jetted from the ink jet head in the ink jet recording device and applied to a formation region of the electromagnetic wave shielding layer on the electronic substrate heated to 60° C. After a lapse of 10 seconds from a time point at which the last ink droplet was landed on the electronic substrate, the ink C1 for forming an electromagnetic wave shielding layer applied onto the electronic substrate was heated at 160° C. for 20 minutes by using a hot plate.

By repeating A set of the application of the ink C1 for forming an electromagnetic wave shielding layer and the heating by the hot plate eight times, an electromagnetic wave shielding layer having a thickness of 3.2 μm was formed.

A pattern of the electromagnetic wave shielding layer was set such that it extends over the insulating protective layer and the ground electrode, covers the insulating protective layer, and is electrically connected to the ground electrode (see FIG. 3A).

In this manner, the internal insulating protective layer, the external insulating protective layer, and the electromagnetic wave shielding layer were formed on the electronic substrate B1 to obtain an electronic device X1.

### <Evaluation>

The following evaluations were executed on the electronic device X1.

The results are shown in Table 1.

### (Short-Circuit)

100 electronic devices X1 were manufactured, and it was confirmed in each of the 100 electronic devices X1 whether a short-circuit between the electromagnetic wave shielding layer and the conductive component outside the ground region occurs as a short-circuit caused by the outflow and/or the mist of the ink for forming an electromagnetic wave shielding layer.

Based on the confirmed results, the short-circuit was evaluated according to the following standard.

In the following evaluation standard, a case in which the short-circuit was most suppressed is ranked “4”.

### —Evaluation Standards for Short-Circuit—

4: The number of occurrences of the electronic device X1 with a short-circuit was 0 out of 100.
3: The number of occurrences of the electronic device X1 with a short-circuit was 1 out of 100.
2: The number of occurrences of the electronic device X1 with a short-circuit was 2 to 5 out of 100.
1: The number of occurrences of the electronic device X1 with a short-circuit was 6 or more out of 100.

### (Formation Stability of Electromagnetic Wave Shielding Layer)

In the above-described manufacture of the electronic device X1, the height (height from the mounting surface of the wiring board) of the ink jet head for jetting the ink C1 for forming an electromagnetic wave shielding layer was set to be higher than the height of the highest insulating protective layer by 1 mm, and, in this condition, the ink C1 for forming an electromagnetic wave shielding layer was jetted onto the insulating protective layer to form 50 ink dots. After that, the ink dots were heated at 160° C. for 60 minutes to cure the ink dots, thereby obtaining a dot image.

50 dot images after curing and a periphery thereof were observed with an optical microscope to confirm the presence or absence of satellites (that is, unintended dot-like images) and unintended mist-like images.

Based on the confirmed results, the formation stability of the electromagnetic wave shielding layer was evaluated according to the following standard.

In the following evaluation standard, a case of the best formation stability of the electromagnetic wave shielding layer is ranked “3”.

### —Evaluation Standard of Formation Stability of Electromagnetic Wave Shielding Layer—

3: Neither satellites nor unintended mist-like images were not confirmed.
2: Although satellites smaller than a main droplet (intended dot image) were confirmed, no satellites having a size equal to or larger than that of the main droplet (intended dot image) were confirmed, and no unintended mist-like images were confirmed.
1: At least either of satellites having a size equal to or larger than that of the main droplet (intended dot image) or unintended mist-like images was confirmed.

### Examples 2 to 5

The same operation as in Example 1 was performed, except that the thickness of the external insulating protective layer on the adjacent conductive component was changed as shown in Table 1.

The results are shown in Table 1.

### Examples 6 to 10

The same operation as in Example 1 was performed, except that the distance between the ground electrode and the adjacent conductive component was changed as shown in Table 1 by changing the design of the LTE module for obtaining the electronic substrate B1.

The results are shown in Table 1.

### Example 11

The same operation as in Example 1 was performed, except that the ink A1 for forming an insulating protective layer was changed to the following ink E1 for forming an insulating protective layer.

The results are shown in Table 1.

### (Preparation of Ink E1 for Forming Insulating Protective Layer)

As an ink E1 for forming an insulating protective layer, an ultraviolet curable-type ink “DM-INI-7003” (manufactured by Dycotec) for forming an insulating protective layer containing an epoxy resin was prepared.

### Comparative Example 1

The same operation as in Example 1 was performed, except that no external insulating protective layer was formed on the adjacent conductive component.

The results are shown in Table 1.

TABLE 1

| | | | | Thickness | | | Distance | | | |
|---|---|---|---|---|---|---|---|---|---|---|
| | External insulating | | | of internal | | | between | | | |
| | protective layer | | | insulating | | | ground | | | |
| | | Thickness | | protective | | | electrode | | Evaluation result | |
| | | on adjacent | Height of | layer on | | | and | Composition | | Formation |
| | | conductive | adjacent | electronic | | Height of | adjacent | for forming | | stability of |
| | Presence | component | conductive | component | | electronic | conductive | insulating | | electromagnetic |
| | or | (μm) | component | (μm) | T2 − | component | component | protective | Short- | wave shielding |
| | absence | (T1) | (μm) | (T2) | T1 | (μm) | (mm) | layer | circuit | layer |
| Comparative | Absent | — | 500 | 50 | — | 500 | 1.0 | A1 | 1 | 3 |
| Example 1 | | | | | | | | | | |
| Example 1 | Present | 1 | 500 | 50 | 49 | 500 | 1.0 | A1 | 3 | 3 |
| Example 2 | Present | 3 | 500 | 50 | 47 | 500 | 1.0 | A1 | 4 | 3 |
| Example 3 | Present | 20 | 500 | 50 | 30 | 500 | 1.0 | A1 | 4 | 3 |
| Example 4 | Present | 50 | 500 | 50 | 0 | 500 | 1.0 | A1 | 4 | 2 |
| Example 5 | Present | 100 | 500 | 50 | −50 | 500 | 1.0 | A1 | 4 | 2 |
| Example 6 | Present | 20 | 500 | 50 | 30 | 500 | 0.04 | A1 | 3 | 3 |
| Example 7 | Present | 20 | 500 | 50 | 30 | 500 | 0.1 | A1 | 4 | 3 |
| Example 8 | Present | 20 | 500 | 50 | 30 | 500 | 1.0 | A1 | 4 | 3 |
| Example 9 | Present | 20 | 500 | 50 | 30 | 500 | 5.0 | A1 | 4 | 3 |
| Example 10 | Present | 20 | 500 | 50 | 30 | 500 | 10.0 | A1 | 4 | 3 |
| Example 11 | Present | 20 | 500 | 50 | 30 | 500 | 1.0 | E1 | 4 | 3 |

As shown in Table 1, in Examples 1 to 11 in which the external insulating protective layer was provided on the adjacent conductive component, the short-circuit caused by the outflow and/or the mist of the ink for forming an electromagnetic wave shielding layer in a case of forming the electromagnetic wave shielding layer was suppressed compared to Comparative Example 1 in which the external insulating protective layer was not provided.

It can be seen from the results of Examples 6 to 10 that, in a case in which the distance between the ground electrode and the adjacent conductive component (that is, the closest distance between the outer edge of the ground electrode and the edge of the adjacent conductive component) is 0.1 mm to 10.0 mm (Examples 7 to 10), the short-circuit caused by the outflow and/or the mist of the ink for forming an electromagnetic wave shielding layer in a case of forming the electromagnetic wave shielding layer is further suppressed.

It can be seen from the results of Examples 1 to 5 that, in a case in which the thickness T1 of the external insulating protective layer on the adjacent conductive component is 2 μm to 200 μm (Examples 2 to 5), the short-circuit caused by the outflow and/or the mist of the ink for forming an electromagnetic wave shielding layer in a case of forming the electromagnetic wave shielding layer is further suppressed.

The entire disclosure of Japanese Patent Application No. 2021-130925, filed Aug. 10, 2021, is incorporated into the present specification by reference. In addition, all documents, patent applications, and technical standards described in the present specification are incorporated in the present specification by reference, to the same extent as in the case where each of the documents, patent applications, and technical standards is specifically and individually described.

What is claimed is:

1. An electronic device comprising:
a wiring board having a mounting surface;
a ground electrode that defines a ground region on the mounting surface;
an electronic component that is located on the mounting surface and is disposed in the ground region;
a conductive component that is disposed adjacent to an outer edge of the ground electrode and is electrically insulated from the ground electrode;
an internal insulating protective layer that is disposed in the ground region and covers the electronic component;
an external insulating protective layer that is disposed outside the ground region and covers the conductive component; and
an electromagnetic wave shielding layer that is provided to extend over the internal insulating protective layer and the ground electrode and that covers the internal insulating protective layer and is electrically connected to the ground electrode, the electromagnetic wave shielding layer being a solidified product of an ink for forming an electromagnetic wave shielding layer.

2. The electronic device according to claim 1,
wherein a closest distance between the outer edge of the ground electrode and an edge of the conductive component is 0.1 mm to 10.0 mm.

3. The electronic device according to claim 1,
wherein a thickness T1 of the external insulating protective layer on the conductive component is 2 μm to 200 μm.

4. The electronic device according to claim 1,
wherein a thickness T1 of the external insulating protective layer on the conductive component is thinner than a thickness T2 of the internal insulating protective layer on the electronic component.

5. The electronic device according to claim 1,
wherein the internal insulating protective layer contains an acrylic resin and the external insulating protective layer contains an acrylic resin, or
the internal insulating protective layer contains an epoxy resin and the external insulating protective layer contains an epoxy resin.

6. A manufacturing method of an electronic device, the method comprising:
preparing an electronic substrate including a wiring board having a mounting surface, a ground electrode that defines a ground region on the mounting surface, an electronic component that is located on the mounting surface and is disposed in the ground region, and a conductive component that is disposed adjacent to an outer edge of the ground electrode and is electrically insulated from the ground electrode;
forming an internal insulating protective layer that covers the electronic component in the ground region; and
forming an electromagnetic wave shielding layer that extends over the internal insulating protective layer and the ground electrode and that covers the internal insulating protective layer and is electrically connected to the ground electrode, as a solidified product of an ink for forming an electromagnetic wave shielding layer,
wherein an external insulating protective layer that covers the conductive component is formed outside the ground region before the forming an electromagnetic wave shielding layer.

7. The manufacturing method of an electronic device according to claim 6,
wherein, in the forming an internal insulating protective layer, the internal insulating protective layer and the external insulating protective layer are formed by using an ink for forming an insulating protective layer.

8. The manufacturing method of an electronic device according to claim 7,
wherein, in the forming an internal insulating protective layer, the ink for forming an insulating protective layer is applied by an ink jet recording method, a dispenser method, or a spray method to form the internal insulating protective layer and the external insulating protective layer.

9. The manufacturing method of an electronic device according to claim 7,
wherein the ink for forming an insulating protective layer is an active energy ray curable-type ink.
